(19) United States
(12) Patent Application Publication
(10) Pub. No.: US 2007/0241664 A1
(43) Pub. Date: Oct. 18, 2007

(54) Organic Electroluminescence Display Device

(76) Inventors: Hirotsugu Sakamoto, Chiba (JP); Shinichi Kato, Mobara (JP); Masatomo Terakado, Chiba (JP); Toshiyuki Matsuura, Mobara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/733,241

(22) Filed: Apr. 10, 2007

(30) Foreign Application Priority Data
Apr. 12, 2006 (JP) 2006-110141

(51) Int. Cl. H05B 33/14; H05B 33/00; H01L 51/50

(52) U.S. Cl. 313/503; 313/500; 313/505

(57) ABSTRACT

An organic electroluminescence display device with high luminescence and high display quality comprises a plurality of active elements, and a plurality of organic electroluminescence elements which produce luminescence through control by the active elements, on a substrate; wherein the organic electroluminescence element has a structure in which a lower electrode, an organic layer, and an upper electrode CD are laminated in this order from the substrate side; the upper electrode CD of the plurality of organic electroluminescence elements is formed as an electrode common to all the organic electroluminescence elements; an electrode is prepared between the upper electrode CD and the organic layer; and the sheet resistance between two points on the upper electrode CD which sandwich the electrode is lower than that between two points which do not sandwich the metal electrode.

### CLAIM OF PRIORITY

The present application claims priority from Japanese Application JP 2006-110141 filed on Apr. 12, 2006, the content of which is hereby incorporated by reference into this application.

### BACKGROUND OF THE INVENTION

1. Field of the Invention

The present invention relates to an organic electroluminescence display device.

2. Description of the Related Art

A top-emission type (hereinafter referred to as “TE type”) active matrix organic electroluminescence display device (hereinafter referred to as “AM-OLED”) is largely different from the bottom-emission type (hereinafter referred to as “BE type”) AM-OLED, a preceding developed product, in the direction of luminescence extraction.

The BE type AM-OLED has a structure (hereinafter referred to as “organic electroluminescence element”) including a laminated structure of a lower electrode on the TFT substrate side, a functional layer OLBF containing a luminescence layer formed by an organic layer, and an upper electrode CD, on an active matrix substrate (hereinafter referred to as “TFT substrate”) which drives each pixel PXL arranged in a matrix form by means of active elements; forms an ITO, i.e., a transparent conductive film, for each pixel PXL as the lower electrode; and performs display by controlling the current flowing into the luminescence layer formed on the ITO by means of the active elements. Since luminescence produced from the luminescence layer is extracted on the TFT substrate side, the upper electrode CD formed on the luminescence layer has a structure in which a metal with high reflection characteristics is collectively formed on the front surface of the effective display area AR. Since the metal having such high reflection characteristics reveals a low sheet resistance, the potential can fully be fed back to the drive circuit as a common electrode for each pixel PXL.

In the case of the TE type AM-OLED, on the other hand, since luminescence of the luminescence layer is extracted not on the TFT substrate side but on the upper electrode CD side, it is necessary to use a metal having reflection characteristics as the lower electrode and a transparent conductive film as the upper electrode CD. The transparent conductive films mentioned here include not only In, Zn, and Sn-containing oxide films, such as IZO, ITO, ZnO, etc., generally referred to as transparent conductive films, but also thin film Ag and thin film Al. An electrode formed by these transparent conductive films has a high sheet resistance. Therefore, only if the electrode is collectively formed as an upper electrode CD over the entire surface of the effective display area AR, potential gradient is produced resulting in luminance inclination in the screen.

Japanese Patent Laid-open No. 2001-230086 and Japanese Patent Laid-open No. 2002-318556 disclose methods for segmentalizing a transparent conductive film into sort of small areas using a metal auxiliary electrode in order to apparently reduce the electrical resistance of the transparent conductive film on the luminescence extraction side. Japanese Patent Laid-open No. 2001-230086 discloses a structure below a bank that is an insulating film between lower electrodes, in which separated auxiliary wiring in the same layer as the lower electrode is prepared, and the auxiliary wiring and the upper electrode CD are connected by means of a contact hole. Japanese Patent Laid-open No. 2002-318556 discloses a method for preparing auxiliary wiring in an area overlapping with the bank, above the upper electrode CD of the organic electroluminescence element.

### SUMMARY OF THE INVENTION

In the case of Japanese Patent Laid-open No. 2001-230086, connection between the auxiliary electrode and wire arrangements below the lower electrode of the organic electroluminescence element is made by a contact hole. If one of the functional layers OLBF of the organic electroluminescence element, containing the luminescence layer, is formed in a contact hole, electrical connection is disabled. Therefore, it is necessary to prepare a non-formation area near the contact hole, which is not smaller than formation shift of the functional layer OLBF. Specifically, according to the technology of Japanese Patent Laid-open No. 2001-230086, it was not avoidable to reduce the opening ratio (ratio of the luminescence area per pixel PXL (bank opening area) to the total area of one pixel PXL).

In the case of Japanese Patent Laid-open No. 2002-318556, the auxiliary electrode is formed above the upper electrode CD, i.e., at a position nearer the display surface than that in the case of Japanese Patent Laid-open No. 2001-230086. Therefore, reflection of the auxiliary electrode is seen as a clear pattern on the screen because of reflection characteristic difference between the auxiliary electrode and the lower electrode.

An object of the present invention is to provide a bright TE type AM-OLED with little on-screen luminance unevenness.

The present invention employs, for example, the following means in order to attain the above-mentioned object.

In the case of the TE type AM-OLED wherein the organic electroluminescence element has a structure in which a lower electrode, a functional layer OLBF containing an organic luminescence layer, and an upper electrode CD are laminated in this order from the TFT substrate side; the upper electrode CD is formed as an electrode common to all the organic electroluminescence elements, i.e., a plain electrode, and the auxiliary electrode made of a material with a conductivity higher than that of the upper electrode CD is formed between the upper electrode CD and the functional layer OLBF.

In other words, if such a structure is to be employed, the auxiliary electrode is formed between the upper electrode CD that is a plain electrode and the functional layer OLBF; and the sheet resistance between two points on the upper electrode CD which sandwich the auxiliary electrode is lower than that between two points on the upper electrode CD which do not sandwich the auxiliary electrode.

In this manner, in-plane voltage drop can be suppressed by lowering the sheet resistance of the entire electrode above the functional layer OLBF combined with the upper electrode CD using a metal with a resistance lower than that of the upper electrode CD as the auxiliary electrode.

With the use of a structure in which the auxiliary electrode is electrically connected to the upper electrode CD between the upper electrode CD and the functional layer OLBF, more specifically, directly beneath the upper electrode CD, the upper electrode CD is sandwiched up to the display surface. Then, since reflected light of the auxiliary electrode becomes out of focus, on-screen luminance unevenness by reflection of the auxiliary electrode decreases, thus improving the display quality.

An aspect preferred as the shape, structure, formation position, etc. of the auxiliary electrode is shown below.

### (1) Structure in the Normal Line Direction: on Bank

When employing a structure with an insulating film which divides pixels PXL, generally referred to as “bank”, between the lower electrode and the functional layer OLBF, it is normally preferable to form the structure at a position of overlapping with the bank. The bank is a non-luminescence area and therefore the opening ratio (luminescence area divided by the total area of pixel PXL) can be maintained high. Furthermore, if the auxiliary electrode eats into the functional layer OLBF, electric field may concentrate on the edge of the auxiliary electrode which may cause leak current between the auxiliary electrode and the lower electrode. However, leak current hardly arises on the bank where the auxiliary electrode is far from the lower electrode exposed from the bank.

In other words, this arrangement can also be referred to as a structure comprising structure A in which the lower electrode, the bank, at least one functional layer OLBF, the auxiliary electrode, and the upper electrode CD are laminated in this order; and structure B in which the insulating film below the lower electrode, the bank, at least one functional layer OLBF, the auxiliary electrode, and the upper electrode CD are laminated in this order. However, the reason why “at least one functional layers OLBF” is included in the laminated body comprising structures A and B is that an area without evaporation on the bank may arise because of a shift due to evaporation during coating evaporation. Conversely, however, there is normally at least one layer with plain evaporation and therefore at least one functional layer OLBF is included.

### (2) Planar Arrangement: Between Luminescence Areas (Between Pixels PXL)

A preferable planar position of the auxiliary electrode is an area between the luminescence areas of each pixel PXL. Since this area is a non-luminescence area, the opening ratio (luminescence area per pixel PXL divided by the area of one pixel PXL) can be maintained high. In other words, it can also be referred to as an area between neighboring organic electroluminescence elements or an area between lower electrodes. Furthermore, depending on wiring layout, these areas are corresponding to an area of overlapping with wiring of the source electrode layer (including vertical drive circuit VDRV, current supply line, and control line) and an area of overlapping with wiring of the gate electrode layer (including scanning line, current supply line, and control line). Furthermore, as mentioned later, it is highly possible that a higher flatness be obtained on the bank in these areas.

### (3) Shape and Planar Layout

If organic electroluminescence elements have been arranged in a matrix form, they can be overlapped with wiring in the column direction, such as the vertical drive circuit VDRV and the current supply line, as well as wiring in the row direction, such as the scanning line, by arranging them in the row or column directions on the screen. Even if an organic flat layer is used for the insulating film below the auxiliary electrode, there are eased asperities. If an inorganic insulating film is used, large asperities are produced below the auxiliary wiring. These forms of wiring include a flat surface extending over a plurality of pixels PXL and therefore have relatively small asperities, making it easier to form an electrode with a uniform thickness.

### (4) Wiring Layout Outside the Effective Display Area AR

If the auxiliary electrode is formed outside the effective display area AR (entire area of luminescence pixels PXL), common voltage VCOM can be applied without using the upper electrode CD. Furthermore, planar layout of the auxiliary electrode without reduction of the opening ratio becomes possible, improving the degree of design freedom. Furthermore, since the common voltage VCOM can be supplied from various directions of the effective display area AR, voltage drop can be suppressed effectively. Specifically, it is preferable that wiring be arranged outside the row direction of the effective display area AR (direction in which the vertical drive circuit VDRV called drain driver is located, in other words, direction in which the vertical drive circuit VDRV is arranged) and the row direction (direction in which the horizontal drive circuit HDRV called gate driver is located, in other words, direction in which the scanning line is arranged). A frame form surrounding all the pixels PXL can suppress voltage drop most.

### (5) Structure for Supplying Common Voltage VCOM

If this auxiliary electrode is connected with wiring below the functional layer OLBF outside the effective display area AR, the common voltage VCOM can be supplied to the screen through the auxiliary electrode having a lower sheet resistance, without using the upper electrode CD having a high resistance. This allows suppression of voltage drop in the effective display area AR.

### (6) Structure 1 for Stable Supply of Common Voltage VCOM

If the upper electrode CD is prepared above the auxiliary electrode at the connecting section in (5), the upper electrode can be arranged so that the entire functional layer OLBF be covered. This allows the upper electrode to function also as a protection layer or a sealing layer. Furthermore, it can function also as an oxidization suppression film or a protection layer for the wiring connected to the auxiliary electrode and the auxiliary electrode.

### (7) Structure 2 for Stable Supply of Common Voltage VCOM

It is preferable that an electrode used to apply the common voltage VCOM to the upper electrode CD be arranged in the same layer as the source electrode of the active element. When constituting a channel of the active element with low-temperature polysilicon, the gate electrode is annealed by means of excimer laser, etc. Therefore, a high melting point metal, such as tungsten, titanium, molybdenum, etc., is used for the gate electrode layer. These high melting point metals have a high resistance. For wiring in the same layer with the same material as the source electrode of the active element, a material having a low resistance, such as aluminum alloys, is normally used. Such a material can be employed because the formation of the source electrode layer is not followed by any high-temperature processes in which aluminum alloys are melted like the laser annealing process. Therefore, it is preferable that a source electrode layer having a low wiring resistance be used in order to suppress the reduction of the common voltage VCOM. However, connection to the wiring in the same layer as the gate electrode is also possible. In this case, however, although the wiring resistance slightly increases, using this layer together improves the degree of freedom of wiring arrangements.

### (8) Structure 3 for Stable Supply of Common Voltage VCOM

A thick insulating film is formed between the source electrode layer and the auxiliary wiring layer. Therefore, it is not possible to obtain stable electrical connection with the source electrode unless a large contact hole is formed. Therefore, from the viewpoint of stable supply of the common voltage VCOM, a preferable structure is such that an electrode in the same layer with same material as the electrode layer contained in the lower electrode is arranged between the upper electrode CD and the wiring below the lower electrode, and connected with these both electrodes.

### (9) Luminescence Type, and Material and Thickness of Electrode

The most effective structure using auxiliary wiring is realized by the TE type. The inventors think it preferable to use, as the upper electrode CD, a transparent conductive film, i.e., a thin film of a low-resistance metal, such as silver, aluminum, etc., formed so thinly that light penetrates, or an electrodes, such as ITO, IZO, ZnO, etc.; and think it preferable to use, as the lower electrode, a metal electrode which is so thick that light does not actually penetrate.

Furthermore, it is preferable that ITO, IZO, ZnO, and a thin metal film be employed as a light-permeable electrode. This structure makes it possible to suppress on-screen luminance unevenness, such as in-plane spot patterns, without reducing the opening ratio.

According to the present invention, it is possible to alleviate in-plane luminance unevenness and nonuniform reflection characteristics while maintaining a high opening ratio.

### BRIEF DESCRIPTION OF THE DRAWINGS

FIG. 1 is a perspective view showing the appearance of an OLED.

FIG. 2 is a cross-sectional view showing an organic electroluminescence display device of the present invention.

FIG. 3 is a block diagram of a first substrate SUB1 and a second substrate SUB2.

FIG. 4 is a block diagram on the first substrate SUB1.

FIG. 5 is a structural drawing showing the layer of the first substrate SUB1.

FIG. 6 is a schematic diagram of an organic electroluminescence element.

FIG. 7 is a block diagram of the first substrate SUB1.

FIG. 8 is a block diagram of the first substrate SUB1 with an auxiliary electrode printed thereon.

FIG. 9 is a structural drawing showing a cross-section of the first substrate SUB1 taken along the C-D and E-F lines of FIG. 7.

FIG. 10 is a structural drawing showing a cross-section of the first substrate SUB1 taken along the G-H and I-J lines of FIG. 7.

FIG. 11 is a structural drawing showing a cross-section of the first substrate SUB1 taken along the C-D and E-F lines of FIG. 7.

FIG. 12 is a structural drawing showing a cross-section of the first substrate SUB1 taken along the C-D and E-F lines of FIG. 7.

FIG. 13 is a structural drawing showing a cross-section of the first substrate SUB1 taken along the C-D and E-F lines of FIG. 7.

FIG. 14 is a structural drawing showing a cross-section of the first substrate SUB1 taken along the C-D and E-F lines of FIG. 7.

FIG. 15 is a structural drawing showing a cross-section of the first substrate SUB1 taken along the C-D and E-F lines of FIG. 7.

FIG. 16 is a structural drawing showing a cross-section of the first substrate SUB1 taken along the C-D and E-F lines of FIG. 7.

FIG. 17 is a structural drawing showing a cross-section of the first substrate SUB1 taken along the C-D and E-F lines of FIG. 7.

FIG. 18 is a block diagram of the first substrate SUB1 when there is a dummy pixel DPXLPXL.

FIG. 19 is a block diagram of the first substrate SUB1 with an auxiliary electrode printed thereon.

FIG. 20 is an example cross-sectional structure of the first substrate SUB1 taken along the G-H and I-J lines of FIG. 19.

FIG. 21 is an example of cross-sectional structure of the first substrate SUB1 taken along the I-J, C-D, and E-F lines of FIG. 20.

FIG. 22 is a diagram showing the planar layout of the auxiliary electrode.

FIG. 23 is a diagram showing the planar layout of the auxiliary electrode.

FIG. 24 is a diagram showing the planar layout of the auxiliary electrode.

FIG. 25 is a diagram showing the planar layout of the auxiliary electrode.

FIG. 26 is a diagram showing the planar layout of the auxiliary electrode.

FIG. 27 is a diagram showing the planar layout of the auxiliary electrode.

FIG. 28 is a diagram showing the planar layout of the auxiliary electrode.

FIG. 29 is a diagram showing the planar layout of the auxiliary electrode.

FIG. 30 is a diagram showing the planar layout of the auxiliary electrode.

FIG. 31 is a diagram showing the planar layout of the auxiliary electrode.

### DESCRIPTION OF SYMBOLS

SUB1 . . . First substrate
SUB2 . . . Second substrate
FF . . . . Front frame
BF . . . Back frame
FPC1 . . . Flexible circuit substrate
SUB3 . . . Third substrate
OLBF . . . Functional layer

### DETAILED DESCRIPTION OF PREFERRED EMBODIMENTS

The present embodiment will be explained below.

### First Embodiment

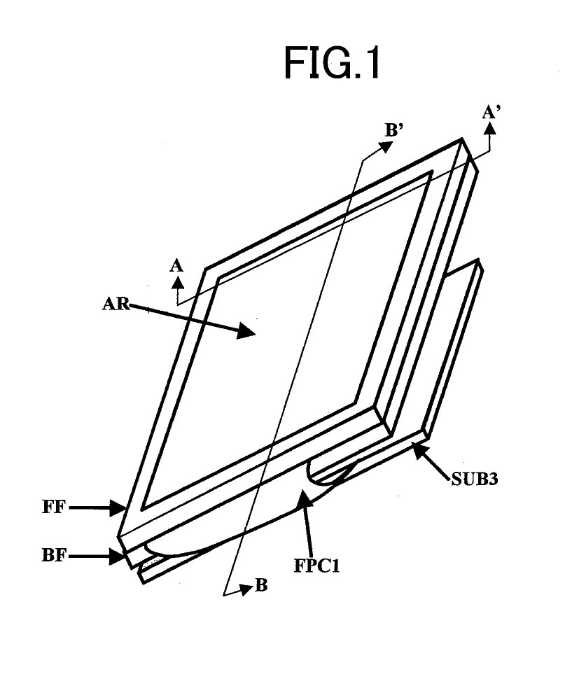

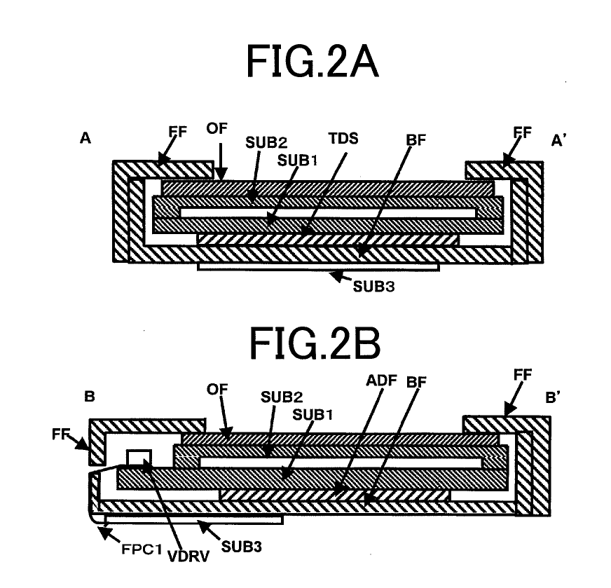

FIG. 1 is a perspective view showing an external appearance of an organic electroluminescence display device. FIG. 2 is a cross-sectional view showing the organic electroluminescence display device of the present invention. FIG. 2A is a cross-sectional view taken along the A-A′ line of FIG. 1. FIG. 2B is a cross-sectional view taken along the B-B′ line of FIG. 1. A TFT substrate with an organic electroluminescence element and an active element formed thereon has a structure comprising a second substrate SUB2 which encloses the organic electroluminescence element of a first substrate SUB1, a front frame FF and a back frame BF which mount the enclosure structure for the first substrate SUB1, a flexible circuit substrate FPC1 connected to the first substrate SUB1, and a third substrate SUB3 connected to the flexible circuit substrate FPC1.

An opening is prepared on the front frame FF. This opening is slightly larger than the effective display area AR, in which organic electroluminescence elements are formed, on the first substrate SUB1 so that a lower electrode of the organic electroluminescence element is visible through the second substrate SUB2. (The functional layer OLBF is transparent and therefore invisible). Although the front frame FF is made of stainless steel and ferrous alloys, plastics are acceptable.

Like the front frame FF, the back frame BF is also made of stainless steel and ferrous alloys, and plastics are also acceptable. The front frame FF and the back frame BF are fit together using snap fits to maintain a fixed amount of space. The first substrate SUB1, the second substrate SUB2, and an optical film OF are stored in the maintained space.

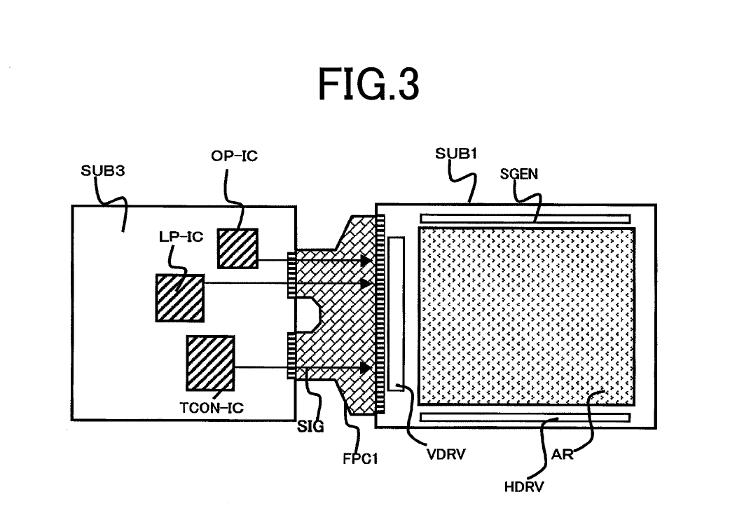

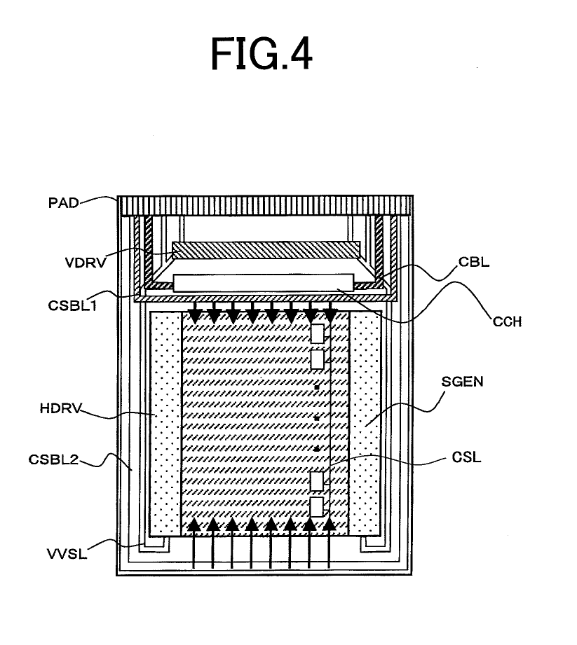

FIG. 3 is a block diagram showing the first to third substrates SUB1-3. FIG. 4 is a block diagram of the first substrate SUB1. The first substrate SUB1 is fixed to the back frame BF (FIG. 2) using adhesive. A vertical drive circuit VDRV including semiconductors IC is mounted on the first substrate SUB1 through COG-mounting, and a flexible circuit substrate FPC1 is connected to a terminal PAD. The second substrate SUB2 is fixed to the first substrate SUB1 using seal agent mixing spacer with the first substrate SUB1. The second substrate SUB2, being arranged between the display surface and the first substrate SUB1, is a light-permeable substrate specifically made of glass. A concave portion is formed on the second substrate SUB2, and light-permeable drying agent is applied to the space. However, if drying agent is not applied, it would be possible to fill the space with resin.

The third substrate SUB3 is fixed to the back side of the second substrate SUB2, and a terminal on the opposite side of the flexible substrate is connected to a terminal of the third substrate SUB3. Furthermore, the third substrate SUB3 includes an OLED power supply circuit which functions as a power supply for driving the organic electroluminescence element, an LTPS power supply circuit which drives a thin-film transistor made of low-temperature polysilicon, and a timing control circuit which outputs a grayscale signal and a timing signal. These signals are supplied to the first substrate SUB1 through the flexible substrate FPC1.

The optical film OF shown in FIG. 2 has a structure in which an electrostatic antireflection layer, a linear polarization layer, an adhesion layer, a λ/2 phase plate, an adhesion layer, a λ/4 phase plate, an adhesion layer, a viewing angle compensation layer, an adhesion layer, a cholesteric liquid crystal layer, an adhesion layer, and a protection layer are laminated in this order from the front frame FF side. The viewing angle compensation layer is a layer which compensates the viewing angle dependency of transmitted light by the cholesteric liquid crystal layer. The optical film OF constitutes a circular polarization plate with the linear polarization plate and the phase plates of the two layers, constitutes a polarization split film with the cholesteric liquid crystal layer, and compensates the viewing angle dependency caused by the polarization split film by means of the viewing angle compensation layer. The optical film OF adheres to the second substrate SUB2 and is fixed by the fitting force of the front frame FF and the back frame FR.

As shown in FIG. 4, the first substrate SUB1 includes a pad PAD, a vertical drive circuit VDRV, a first current supply bus line CSBL1, a second current supply bus line CSBL2, a cathode bus line CBL, a horizontal drive circuit HDRV, a signal line for the horizontal drive circuit HDRV, a cathode contact CCH, and the effective display area AR (FIG. 3). The pad PAD is connected with the flexible substrate FPC1.

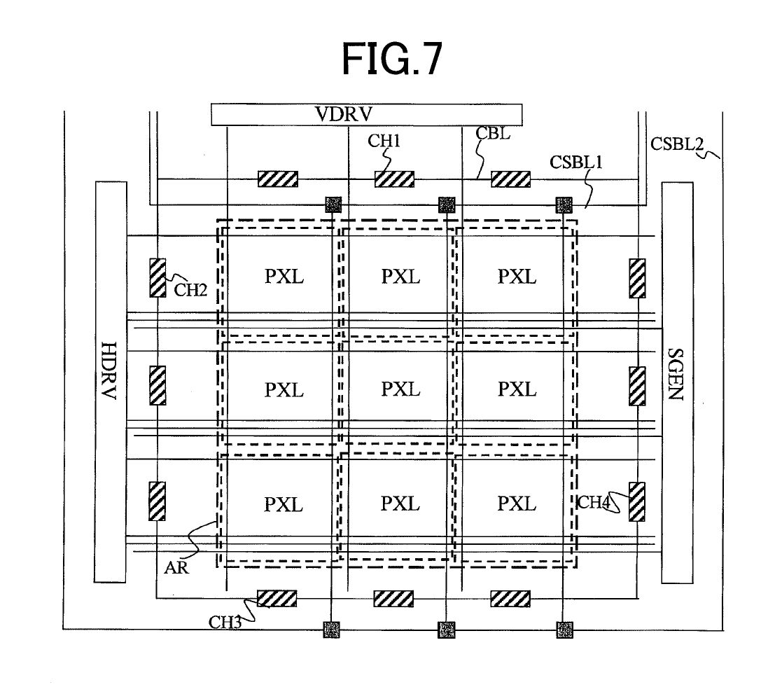

As mentioned above, the vertical drive circuit VDRV, which is mounted by the COG mount technique, receives signals Sig, such as a picture signal, power, timing signal, etc., through the pad PAD; and supplies grayscale data to a pixel PXL (mentioned later in FIG. 7) in the effective display area AR through the vertical drive circuit VDRV which extends vertically. Furthermore, the vertical drive circuit VDRV supplies a timing signal, LTPS power, signal power, and a synchronization signal for synchronization with the vertical drive circuit VDRV, to the horizontal drive circuit HDRV and a triangular wave generation circuit SGEN.

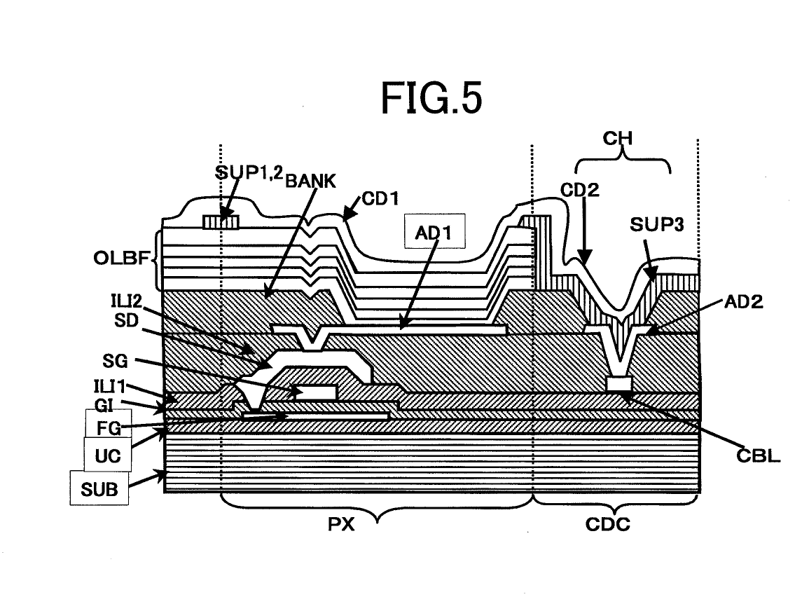

Common voltage (hereinafter referred to as VCOM) to be supplied to the upper electrode CD of an organic electroluminescence element mentioned later is applied to the cathode bus line CBL. Then, the cathode bus line is formed vertically on both sides of the vertical drive circuit VDRV from the pad PAD, and then horizontally between the vertical drive circuit VDRV and the effective display area AR, making connection of both sides. Furthermore, the cathode bus line CBL is formed between the horizontal drive circuit HDRV and the effective display area AR and between the triangular wave generation circuit SGEN and the effective display area AR, i.e., vertically in the external area in the row direction of the effective display area AR, and further formed horizontally below the effective display area AR (along the side facing the vertical drive circuit VDRV), making connection of both sides. However, this section is omitted in FIG. 4. Details will be mentioned later in FIG. 5.

The first current supply bus line CSBL1 is formed vertically on both sides of the vertical drive circuit VDRV from pad PAD, and then horizontally between the cathode bus line CBL and the effective display areas AR, making connection of both sides. The first current supply bus line CSBL1 is formed vertically in FIG. 4, i.e., along the direction in which the vertical drive circuit VDRV extends, and current supply lines CSL for supplying current to arranged pixels PXL are connected in the direction thereof. In FIG. 4, a cathode contact CCH is formed for the upper side of the effective display area AR and connected with the upper electrode CD at the cathode contact CCH, and supplies the common voltage VCOM to the upper electrode CD. The structure of connections at the cathode contact CCH will be mentioned later. Although FIG. 4 illustrates the cathode contact CCH formed above the effective display area AR for simplification, it is actually formed on the four outer sides of the effective display area AR. This configuration will be explained in detail in FIG. 7.

The second current supply bus line CSBL2 is formed on both sides of the vertical drive circuit VDRV from the pad PAD, further formed vertically on the outer side of the horizontal drive circuit HDRV and the triangular wave generation circuit SGEN, and further formed horizontally to the bottom of the effective display area AR, making connection of both sides.

The horizontal drive circuit HDRV is a circuit generally referred to as gate driver, which is the LTPS built in the substrate with the present embodiment. Furthermore, in the case of the present embodiment, three scanning lines per pixel PXL extend horizontally (in the row direction) from the horizontal drive circuit HDRV.

The triangular wave generation circuit, a circuit required for a pixel PXL circuit previously developed by the present applicant, supplies one triangular wave per frame.

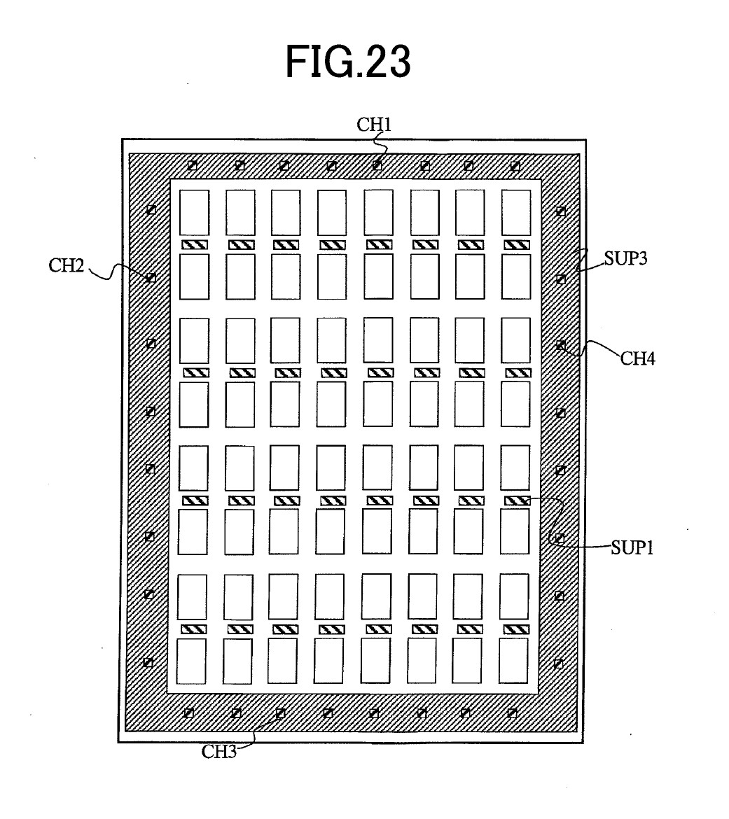

For the above-mentioned drive circuit and triangular wave generation circuit, the circuits and drive waveforms described particularly in FIG. 23 to FIG. 25 in patent application No. 2006-51346 previously applied by the present applicant are used. Since detailed explanations are given in the application allowing cross-reference, the present specification will not explain the details.

The layer structure of the first substrate SUB1 is shown in FIG. 5. The first substrate SUB1 has a structure in which a glass substrate SUB, a undercoat layer UC, a polysilicon layer FG, a first insulation layer GI, a first electrode layer SG, a second insulation layer ILI1, a second electrode layer SD, a third insulation layer ILI2, a third electrode layer AD, a fourth insulation layer BANK, a functional layer OLBF, a fourth electrode layer SUP, and a fifth electrode layer CD are formed in this order.

The undercoat layer UC formed on the glass substrate SUB is a laminated film of SiO and SiN. This laminated film, which is an antidiffusion film which prevents diffusion of Na from glass to the polysilicon layer FG, is formed by means of the low pressure chemical vapor development method (the LPCVD method).

Then, an amorphous silicon layer a-Si with 50-nm film thickness is formed on the glass substrate SUB by use of the low pressure chemical vapor development method (LPCVD method). Then, by performing laser annealing of the entire film surface with excimer laser, a-Si is crystallized to form the polysilicon layer FG made of polycrystal silicon p-Si.

Then, the polysilicon layer FG is patternized through dry etching to form a channel (active layer) area for transistors. Then, the first insulation layer GI was formed with a SiO2 film with 100-nm film thickness by use of the plasma-enhanced chemical vapor development method (PECVD method). This first insulation layer GI functions as a gate insulating film.

Then, as the first electrode layer SG, a TiW film with 50-nm film thickness is produced by means of the sputtering method and then patterning performed. This patterning forms the gate electrode of the thin film transistor, wiring horizontally extending from the above-mentioned horizontal drive circuit HDRV and triangular wave generation circuit SGEN, and other wiring. This wiring may be MoW wiring.

Then, n-ion is injected into the patternized polysilicon layer from above the gate insulating film by means of the ion-injection method. n-ion is not injected into an area having the gate electrode thereabove, which becomes an active layer.

Then, heat-activation treatment is performed on of the first substrate SUB1 under inactive N₂ atmosphere to allow doping to be performed effectively. On the above-mentioned layer, a silicon nitride (SiNx) film is formed as a second insulation layer ILI1. The film thickness is 200 nm.

Then, a contact hole is formed in the first insulation layer GI and the second insulation layer ILI1 above both ends of the active layer. On the above-mentioned layer, the second electrode layer SD made of Al with 500-nm film thickness is formed by means of the sputtering method. Through patterning with a photo-lithography process, the vertical drive circuit VDRV, wiring vertically extending such as the current supply line CSL, the cathode bus line CBL, and a source-drain electrode of the thin film transistor, etc. are formed. Furthermore, connection is made with the first electrode layer SG and the polysilicon layer FG through the contact hole.

Then, a SiNx film is formed as a third insulation layer ILI2. The film thickness is 500 nm. A contact hole is prepared on the source electrode of the thin film transistor. On the above-mentioned layer, the third electrode layer AD is formed by means of the sputtering method, in which ITO is laminated on Al with 150-nm thickness. Furthermore, a lower electrode AD1 of the organic electroluminescence element and the relay electrode (pad) AD2 of a cathode contact CH on the cathode bus line CBL are formed through patterning of the third electrode layer by use of the photo-lithography method.

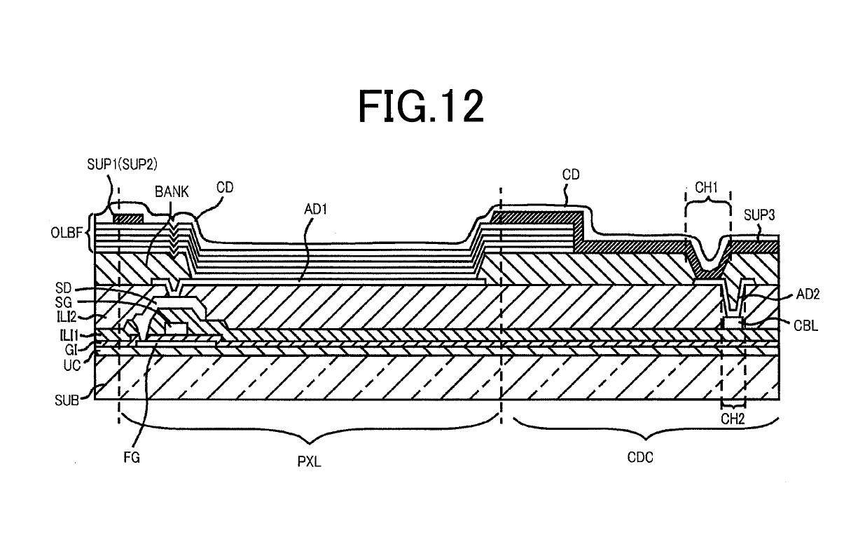

For these drive circuit and the triangular wave generation circuit, circuits described particularly in FIG. 12 to FIG. 22 in patent application No. 2006-51346 previously applied by the present applicant are used. Since detailed explanations are given in the application allowing cross-reference, the present specification will not explain the details.

Then, by use of the spin coat method, a positive photosensitivity protection film is formed as a fourth insulation layer BANK and then bake treatment is performed. The fourth insulation layer BANK with a 1-μm film thickness covered the lower electrode by 3 μm, as well as the surroundings of the cathode contact CH. The fourth insulation layer BANK is a layer referred to as a bank.

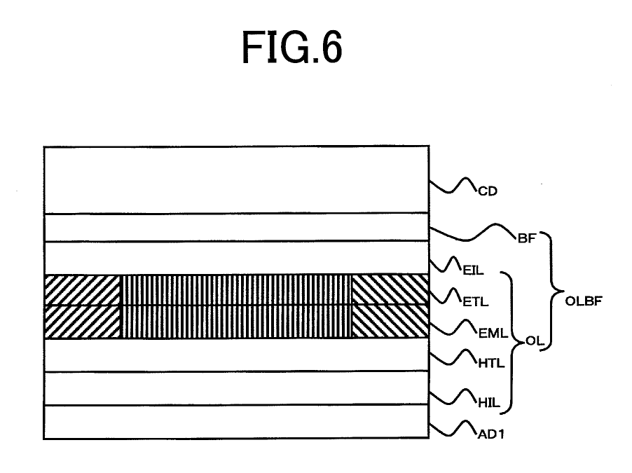

FIG. 6 is a schematic diagram showing an organic electroluminescence element. The structure is such that a hole injection layer HIL, a hole transportation layer HTL, an organic luminescence layer OLE, an electron transportation layer ETL, an electron injection layer EIL, a buffer layer BF, and an upper electrode CD are laminated on the lower electrode AD1. First of all, for the glass substrate SUB formed up to the lower electrode AD1, 3-minute ultrasonic washing is performed using each of acetone and pure water in this order. Spin-drying is performed after the washing. Then, a common evaporation film of F4-TCNQ and copper phthalocyanine with 50-nm film thickness is formed by means of the two-dimensional simultaneous vacuum evaporation method. Shadow masking is used for pattern formation. The molar proportion of F4-TCNQ and copper phthalocyanine is 1:1. The common evaporation film functions as a hole injection layer HIL.

Then, 4,4-bis[N-(1-naphthyl)-N-phenylamino]biphenyl film (hereinafter abbreviated as A-NPD film) with 50-nm film thickness is formed by means of the vacuum evaporation method. Shadow masking is used for pattern formation. The evaporation area is 1.2 times each side of the lower electrode. The A-NPD film functions as a hole transportation layer HTL. On the above-mentioned layer, a common evaporation film of tris(8-quinolinol) aluminum (hereinafter referred to as Alq) and quinacridone (hereinafter referred to as Qc) with 20-nm film thickness was formed by means of two-dimensional simultaneous vacuum evaporation method. Evaporation is performed by controlling the evaporation speed to 40:1. The Alq+Qc common evaporation film functions as a luminescence layer EML. Shadow masking is used for pattern formation.

On the above-mentioned layer, an Alq film with 10-nm film thickness is formed by means of the vacuum evaporation method. The Alq film functions as an electron transportation layer ETL. Shadow masking is used for pattern formation. Then, as an electron injection layer EIL, a Li-doped Alq film is formed by 10 nm by means of the two-dimensional simultaneous vacuum evaporation method. The molar proportion of Alq and Li is 1:1. Shadow masking is used for pattern formation. The buffer layer BF is formed through EB evaporation of vanadium oxide. The film thickness is 15 nm. Shadow masking is used for pattern formation. The composition of the vanadium oxide after evaporation is such that the ratio of vanadium to oxygen is 1:2.2 and the permeability is 95%. The buffer layer may be made of ZnO, SnO2, WO3, MoO3, or V2O5. These layers are formed mainly of an oxide containing a smaller amount of oxygen decomposed and generated during film formation than that included in the material of the upper electrode CD.

Then, the fourth electrode layer SUP is formed with Al with 100-nm film thickness by means of the sputtering method. The auxiliary electrode is formed through patterning. This layout will be mentioned later. Furthermore, the fourth electrode layer SUP may be made of Cu or alloys of Al and Cu, instead of Al. The resistance of the fourth electrode layer SUP is lower than that of the fifth electrode layer CD. When the sheet resistance is measured from the fifth electrode sandwiching the auxiliary electrode having been subjected to patterning, the fourth electrode layer may be formed in such a way that the sheet resistance between two points which sandwich the auxiliary electrode is lower than that between two points which do not sandwich the auxiliary electrode.

Then, an In—Zn—O film (hereinafter abbreviated as IZO film) with 100-nm film thickness is formed as a fourth electrode layer SUP by means of the sputtering method. The IZO film, which functions as an upper electrode CD 125, is a non-crystal oxide film. A target satisfying In/(In+Zn)=0.83 is used. Film formation conditions include Ar:O2 mixture gas as atmosphere, a degree of vacuum of 1 Pa, and a sputtering output of 0.2 W/cm2. The upper electrode CD made of an In—ZnO film functions as a cathode with a permeability of 80%.

Then, a SiOxNy film with 50-nm film thickness is formed by means of the sputtering method. The SiOxNy film functions as a protection layer. This protection film is omitted in the Figures. It is desirable that the hole injection layer HIL mentioned here be made of a material having an appropriate ionization potential in order to lower injection obstructions of the lower electrode AD that is an anode, and the hole transportation layer HIL. Specifically, the material for the hole injection layer HIL may be but is not limited to metal phthalocyanine, starburst amine compound, polyaniline, and polythiophene. Furthermore, it is desirable that hole donative dopant materials have been doped in the hole injection layer. Specifically, desirable hole donative dopant materials include 2,3,5,6-tetrafluoro tetracyano quinodi methane (F4TCNQ), chlorination iron, and dicyano dichloro quinine, but not limited thereto and it would be possible that a plurality of these materials are used together.

The hole transportation layer HTL mentioned here has a role to transport holes and then inject them into the luminescence layer. Therefore, it is desirable that the layer HTL be provided with high hole mobility, chemical stability, and high glass transfer temperature. Preferably, materials for the hole transportation layer HTL include N,N′-bis(3-methylphenyl)-N,N′-diphenyl-[1,1′-biphenyl]-4,4′diamine (TPD); 4,4′-bis[N-(1-naphthyl)-N-phenylamino]biphenyl (α-NPD); 4,4′,4″-tri(N-carbazolyl)triphenylamine (TCTA); and 1,3,5-tris[N-(4-diphenylaminophenyl)phenylamino]benzene (p-DPA-TDAB), but not limited thereto and it would be possible that a plurality of these materials are used together.

The luminescence layer EML mentioned here refers to a layer in which injected holes recombine with electrons to produce luminescence with a wavelength specific to the material. There are two different cases of luminescence: one is luminescence of a host material itself forming a luminescence layer and the other is luminescence of a minute amount of a dopant material added to the host. Preferably, materials for the host include distyrylarylene derivative (DPVBi), silole derivative (2PSP) having the benzene ring as a frame, oxodiazole derivative (EM2) having the triphenylamine structure at both ends, perynone derivative (P1) having the phenanthrene group, oligothiophene derivative (BMA-3T) having the triphenylamine structure at both ends, perylene derivative (tBu-PTC), tris(8-quinolinol) aluminum, polybara-phenylene vinylene derivative, polythiophene derivative, polybara-phenylene derivative, polysilane derivative, and polyacetylene derivative, but not limited thereto and it would be possible that a plurality of these materials are used together.

Then, specifically, desirable dopant materials include quinacridone, coumarin 6, nilered, rubrene, 4-(dicyanomethylene)-2-methyl-6-(paradimethylaminostyryl)-4H-pyran (DCM), and dicarbazole derivative, but not limited thereto and it would be possible that a plurality of these materials are used together.

The electron transportation layer ETL mentioned here has a role to transport electrons and then inject them into the luminescence layer. Therefore, it is desirable that the layer ETL be provided with a high electron mobility. Specifically, desirable materials include tris(8-quinolinol)aluminum, oxadiazole derivative, silole derivative, and zinc benzothiazole complex, but not limited thereto, and it would be possible that a plurality of these materials are used together.

The electron injection layer EIL mentioned here, an organic compound with electron donative dopant materials doped therein, is used to improve the electron injection efficiency from the cathode to the electron transportation layer ETL. Specifically, desirable electron donative dopant materials include lithium, magnesium, calcium, strontium, barium, magnesium, aluminum, alkaline metal compounds, alkaline-earth metal compounds, rare earth metal compounds, organic metal complex containing alkaline metal ion, organic metal complex containing alkaline-earth metals ion, and organic metal complex containing rare earth metal ion, but not limited thereto, and it would be possible that a plurality of these materials are used together. Specifically, desirable host materials for the electron injection layer EIL include tris(8-quinolinol) aluminum, oxadiazole derivative, silole derivative, and zinc benzodiazole complex, but not limited thereto, and it would be possible that a plurality of these materials are used together.

With the above-mentioned configuration, a structure not including the electron injection layer EIL or the hole injection layer HIL is also possible. Furthermore, a structure not including the electron transportation layer ETL or the hole transportation layer HTL is also possible. More specifically, there are three possible cases of the buffer layer: in contact with the organic luminescence layer EML, in contact with the electron transportation layer ETL, and in contact with the electron injection layer EIL.

It is desirable that the anode material used for the lower electrode AD1 be a conductive film having a large work function which improves the efficiency of hole injection. Specifically, possible materials include metals, such as molybdenum, nickel, chromium, etc.; alloys using these metals; and inorganic materials, such as polysilicon, amorphous silicon, tin oxides, indium oxide, indium tin oxide (ITO), etc., but not limited thereto.

If an In2O3-SnO2-containing conductive film is produced at a substrate temperature of about 200 degrees by means of the sputtering method, polycrystal state is attained. In the polycrystal state, the etching speed in the crystal grain differs from that on the crystal grain boundary surface and therefore the amorphous state is desirable when using the film for the lower electrode AD1.

Furthermore, a configuration using the lower electrode AD1 as a cathode and the upper electrode CD as an anode is possible. In this case, the lower electrode AD1, the electron injection layer EIL, the electron transportation layer ETL, the luminescence layer EML, the hole transportation layer HTL, the hole injection layer HIL, and the upper electrode CD are laminated in this order. With the above-mentioned configuration, a structure not including the electron injection layer EIL or not including the hole injection layer HIL is also possible. Furthermore, a structure not including the electron transportation layer ETL or the hole transportation layer HTL is also possible. More specifically, there are three possible cases of the buffer layer: in contact with the organic luminescence layer EML, in contact with the hole transportation layer HTL, and in contact with the hole injection layer EIL.

When the lower electrode AD1 is used as a cathode, it is desirable that the cathode material be a conductive film having a small work function which improves the efficiency of electron injection. Specifically, possible materials include aluminum, aluminum-neodymium alloys, magnesium-silver alloys, aluminum-lithium alloys, aluminum-calcium alloys, aluminum-magnesium alloys, metal calcium, cerium compounds, etc., but not limited thereto.

When the upper electrode CD is used as an anode, possible anode materials include oxides composed mainly of indium oxide. An In2O3-SnO2-containing transparent conductive film and a Sn2O3-ZnO-containing transparent conductive film are particularly desirable. Possible manufacturing methods of a transparent conductive film include the sputtering method, the facing target sputtering method, the EB evaporation method, and the ion plating method.

When the upper electrode CD is formed, a part of an oxide, a composition material of the upper electrode CD, is decomposed and then the generated oxygen radical oxidizes the organic film resulting in luminescence voltage rise. As a result of close study, it is possible to reduce the luminescence voltage rise by organic film oxidization during formation of the upper electrode CD by preparing a buffer layer between the organic film and the upper electrode CD, the buffer layer formed mainly of a conductive oxide having an oxygen-binding force stronger than that of the upper electrode CD.

When using an upper electrode CD formed mainly of indium oxide, for example, possible materials of the buffer layer BF formed mainly of a conductive oxide having an oxygen-binding force larger than that of the upper electrode CD include vanadium oxide, molybdenum oxide, tungsten oxide, tantalum oxide, titanium oxide, niobium oxide, and chromium oxide. On the other hand, a material composed of germanium oxide, copper oxide, ruthenium oxide, etc. has an oxygen-binding force smaller than that of indium oxide, and generates more oxygen radical during buffer layer film formation than during upper electrode CD film formation. Therefore, it is not possible to suppress the luminescence voltage rise.

Furthermore, if the buffer layer BF is explained in other words, it can be referred to as a layer between the organic layer OLE and the upper electrode CD, which is formed mainly of an oxide having a Gibbs energy generated near the melting point lower than that of the composition material of the upper electrode CD. By use of a material, having a lower Gibbs energy generated near the melting point than the main raw material of the upper electrode CD, for the buffer layer, it is possible to reduce the amount of oxygen radical decomposed and generated before and in early stage of film formation, resulting in reduced oxidization of the organic layer.

Still in other words, the buffer layer BF can also be referred to as a layer between the organic layer and the upper electrode CD, which is formed mainly of an oxide having a lower Gibbs energy generated near the melting point than −300 kJ/mol. Voltage rise can be suppressed to 1V or less by using a material having a generated Gibbs energy lower than −300 kJ/mol for the buffer layer BF.

Furthermore, the buffer layer BF is made of a material composed mainly of an oxide having a resistivity of 1×107 Ωcm or less, and a preferable film thickness is 5 nm to 50 nm. When a material having a resistivity of 1×107 Ωcm or more is used for the buffer layer, large voltage drop of 0.1V or more occurs in the buffer layer during high-luminance luminescence, canceling effects of oxidization prevention. Furthermore, organic film oxidization can be suppressed by making a film with a thickness of 5 nm or more; however, it becomes impossible to ignore the efficiency reduction caused by reduced permeability if the film thickness becomes 50 nm or more. For this reason, the above-mentioned configuration is employed.

Furthermore, when the upper electrode CD is used as an anode, it is preferable that the buffer layer be formed mainly of vanadium oxide. It is possible to suppress the voltage rise to almost 0V using the upper electrode CD as an anode and vanadium oxide for the buffer layer. A desirable composition of the vanadium oxide is such that the ratio of oxygen to vanadium is 2 to 5. Furthermore, when the upper electrode CD is used as an anode and vanadium oxide used for the buffer layer, the vanadium oxide is also provided with the function of the hole transportation layer. Therefore, it becomes possible to supply holes directly to the luminescence layer EML without the hole transportation layer HTL and the hole injection layer HIL.

Furthermore, the protection layer is formed on the upper electrode CD aiming at preventing H₂O and O₂ in the atmosphere from getting into the upper electrode CD or the organic layer thereunder. Possible materials for the protection layer include inorganic materials, such as SiO2, SiNx, SiOxN, etc., and organic materials, such as polypropylene, polyethylene terephthalate, polyoxymethylene, polyvinyl chloride, polyvinylidene fluoride, cyanoethyl pulran, polymethyl methacrylate, polysulfone, polycarbonate, polyimide, etc., but is not limited thereto.

FIG. 7 is a block diagram on the first substrate SUB1, showing the diagram in FIG. 4 in more detail. For the simplicity of explanation, FIG. 7 shows nine (3×3) pixels PXL. However, it goes without saying that the present invention also covers VGA, XGA, and other high-resolution display devices.

A plurality of vertical wires including a grayscale signal line DATA extend from the vertical drive circuit VDRV arranged above the effective display area AR. This vertical wiring is formed in the second electrode layer SD. From the first and second current supply bus lines CSBL1 and CSBL2 extending on all four sides of the effective display area AR, the current supply lines CSL which are formed at electrodes of the second electrode layer vertically extend. From the horizontal drive circuit HDRV, three wires for each pixel PXL row extend in order to supply three different signals. This wiring is formed in the first electrode layer SG.

The current supply bus line CSBL, which is formed in the second electrode layer SD, is detoured in the first electrode layer SG only at a portion where the bus line intersects with the vertical drive circuit VDRV. The current supply line CSL is formed along the vertical drive circuit VDRV and formed in the second electrode layer SD.

The cathode bus line CBL runs on both sides of the vertical drive circuit VDRV and then is led outside the effective display area AR, i.e., above (direction from the effective display area AR to the vertical drive circuit VDRV in the case of FIG. 5) and below and on both sides of the effective display area AR. The cathode bus line CBL is provided with contact holes CH1 to CH4 between wiring groups vertically arranged along the current supply line CSL from the vertical drive circuit VDRV and between wiring groups horizontally arranged along three wires extending from the horizontal drive circuit HDRV and a wire extending from the triangular wave generation circuit SGEN. The first contact holes CH1 are arranged between the first current supply bus line CSBL1 and the vertical drive circuit VDRV. The second contact holes CH2 are arranged between the horizontal drive circuit HDRV and the effective display area AR. The third contact holes CH3 are arranged between the second current supply bus line CSBL2 and the effective display area AR. The fourth contact holes CH4 are arranged between the triangular wave generation circuit SGEN and the effective display area AR.

When forming the cathode bus line CBL in the second electrode layer SD, the cathode bus line CBL is detoured in the first electrode layer SG and the third electrode layer at a portion where the bus line intersects with other wiring in the same layer. Furthermore, when forming this cathode bus line CBL in the third electrode layer, the cathode bus line CBL is detoured in the second electrode layer SD and the third electrode layer at a portion where the bus line intersects with other wiring in the same layer.

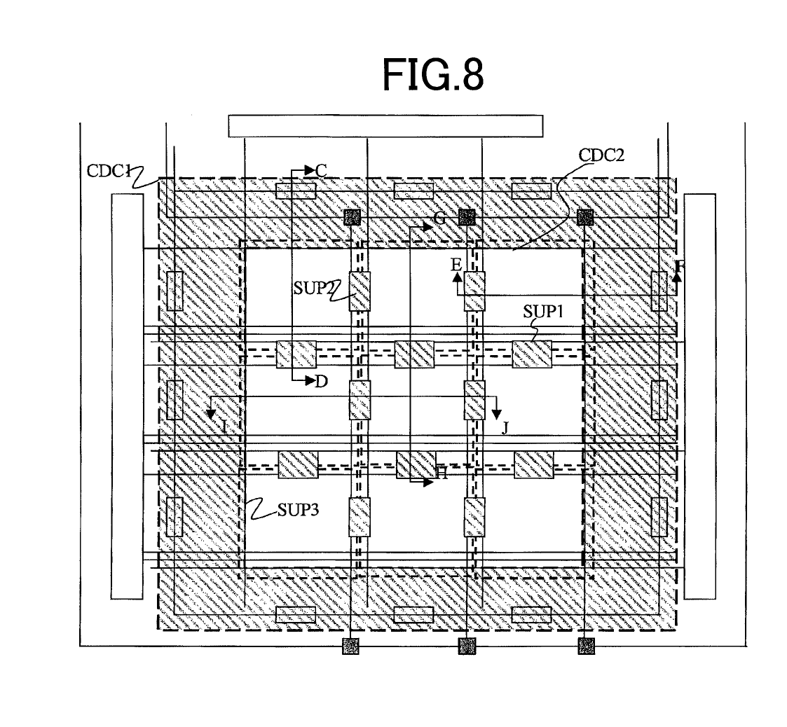

FIG. 8 is a block diagram of the first substrate SUB1, showing the arrangement of the auxiliary electrode. In FIG. 8, cathode contacts CH1 to CH4 are arranged outside all the pixels PXL constituting the outermost edge of the display pixel PXL. Furthermore, first and second auxiliary electrodes SUP1 and SUP2 are formed between all pixels PXL. A first auxiliary electrode SUP1 on a bank between horizontally adjacent pixels PXL is a vertically long rectangle. A plurality of the first auxiliary electrodes SUP1 are vertically arranged in the form of dashed line. With the present embodiment, a solid line of the dashed line has the same length as the horizontal length of the luminescence area, and the point-interval of the dashed line is the same as the horizontal length of the non-luminescence area. A second auxiliary electrode SUP2 on a bank between vertically adjacent pixels PXL is a horizontally long rectangle. A plurality of the second auxiliary electrodes SUP2 are vertically arranged in the form of dashed line. With the present embodiment, a solid line of the dashed line has the same length as the vertical length of the luminescence area, and the point-interval of the dashed line is the same as the vertical length of the non-luminescence area.

Since the first auxiliary electrodes SUP1 and the second auxiliary electrodes SUP2 make it possible to suppress voltage drop produced in the arrangement directions thereof, it is possible to suppress luminance unevenness in each individual direction. A third auxiliary electrode SUP3 around the effective display area AR is formed from a first formation area line CDC1, in the form of a picture frame, i.e., from the outside of the effective display area AR to a second formation area CDC2 on the banks of the outermost pixels PXL. The common voltage VCOM is supplied to the third auxiliary electrode SUP3 by the first to fourth cathode contacts CH1 to CH4 arranged outside each pixel PXL. Since voltage drop produced in the horizontal and vertical directions can be suppressed by preparing the third auxiliary electrode SUP3, it is possible to suppress luminance unevenness in the horizontal and vertical directions. Furthermore, since the cathode contacts CH are arranged horizontally and vertically with respect to the third auxiliary electrodes SUP3 extending horizontally and vertically, suppression of voltage drop is also possible. The upper electrode CD, common to each pixel PXL, extends to the second formation area line CDC2 exceeding the first formation area line CDC1. Since the auxiliary electrodes SUP1, SUP2, and SUP3 suppress voltage drop, metal materials with low resistance are used. For example, Al having a low resistance can easily be formed at low cost. Furthermore, Zn has an advantage of being resistant to corrosion.

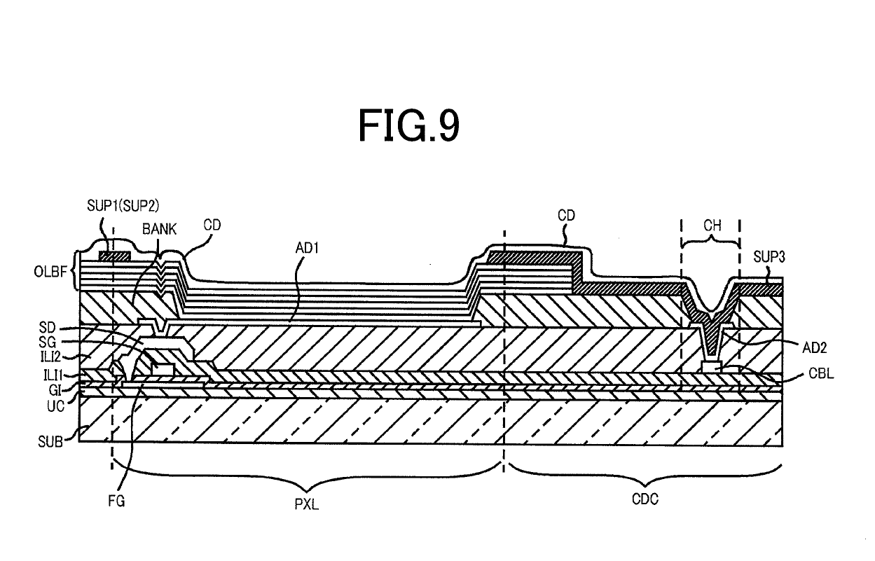

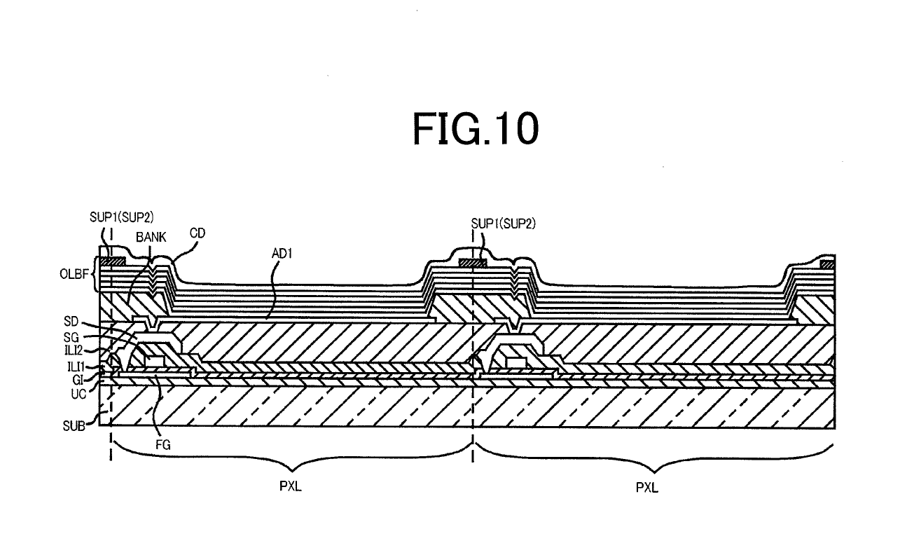

Cross-sectional structures of the first substrate SUB1 taken along the C-D, E-F, G-H, and I-J lines of FIG. 8 are shown in FIG. 9 and FIG. 10. FIG. 9 shows a cross-sectional structure of the first substrate SUB1 taken along the C-D and E-F lines of FIG. 8. The cross-sectional structure of the pixel area PXL is shown on the left-hand side, and the cross-sectional structure of the cathode contact CDC area on the right-hand side of FIG. 9. The fundamental layer structure is the same as the one of FIG. 5. A cathode contact area CDC ranges from the first formation area line CDC1 to the second formation area line CDC2, with a portion included in the pixel area PXL excluded from that range.

On the pixel area PXL formed are: the third insulation layer ILI2 on a thin film transistor with the gate electrode formed in the first electrode layer SG and the source drain electrode formed in the second electrode layer SD; the lower electrode AD1 connected to the source drain electrode of the thin film transistor; a bank BANK delimiting the lower electrodes AD1; the functional layer OLBF including the organic layer EML and the buffer layer formed on the lower electrode AD1; the first auxiliary electrode SUP1; the second auxiliary electrode (SUP2); the upper electrode CD common to all pixels PXL; and a part of the third auxiliary electrode SUP3. The bank having an opening above the lower electrode AD covers the surrounding of the lower electrode AD and the third insulation layer ILI2 and extends beyond the contact hole CH in the cathode contact area.

In the cathode contact area CDC, the functional layer OLBF extending from the pixel area PXL, the third auxiliary electrode SUP3 layer, and the upper electrode CD layer are formed on the third insulating film. At the contact hole CH, a relay electrode AD2 of the same layer as the lower electrode AD1, i.e., the third electrode layer is formed. At the contact hole CH, therefore, the cathode bus line CBL formed in the second electrode layer SD, the relay electrode AD2 formed in third electrode layers AD formed on the contact pad PAD of the cathode bus line CBL, the fourth electrode layer SUP constituting the third auxiliary electrode SUP3 formed on the relay electrode AD2, and the fifth electrode layer CD constituting the upper electrode CD are laminated.

FIG. 10 shows a cross-sectional structure of the first substrate SUB1 taken along the G-H and I-J lines of FIG. 8; it is a cross-sectional view showing the structure of two consecutive pixel areas PXL.

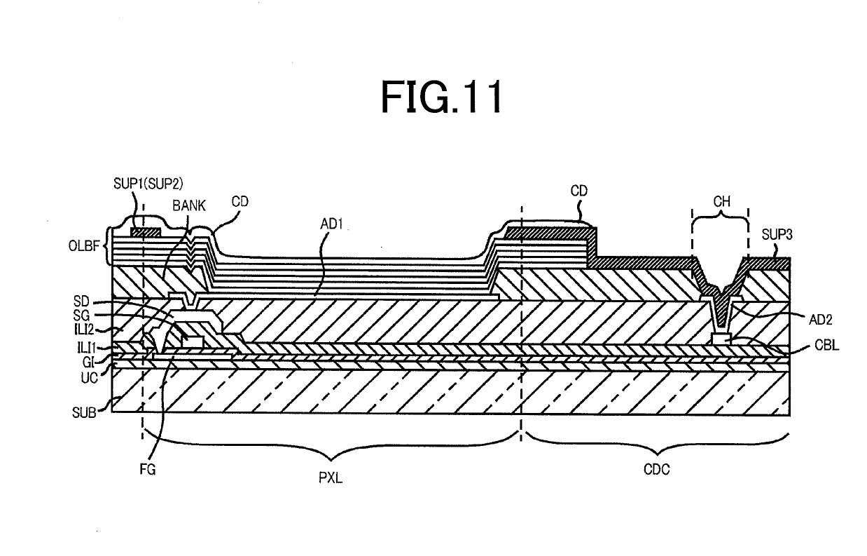

Example cross-sectional structures of the first substrate SUB1 taken along the C-D and E-F lines of FIG. 8 are shown in FIGS. 11 to 17. FIG. 11 differs from FIG. 9 in that the upper electrode CD uses almost the same pattern as that of the functional layer OLBF. FIG. 12 differs from FIG. 9 in that the first contact hole CH1 in the bank which is an opening of the bank, and the second contact hole CH2 which is an opening of the third insulation layer ILI2 are shifted in the planar direction. If the third insulation layer ILI2 or the bank BANK is thick, the taper angle of the contact hole may become steep, or the relay electrode AD2, the third auxiliary electrode SUP3, or the upper electrode CD may incur connection failure. However, the connection reliability can be improved through shift in the planar direction in this manner.

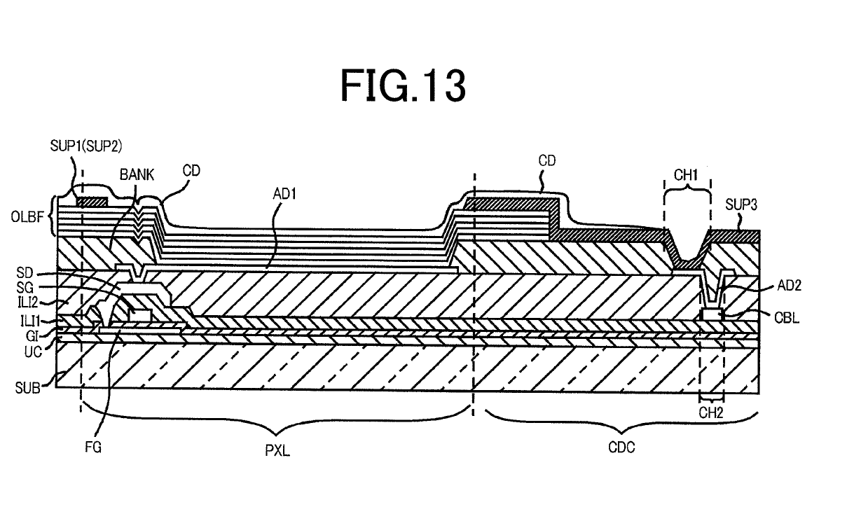

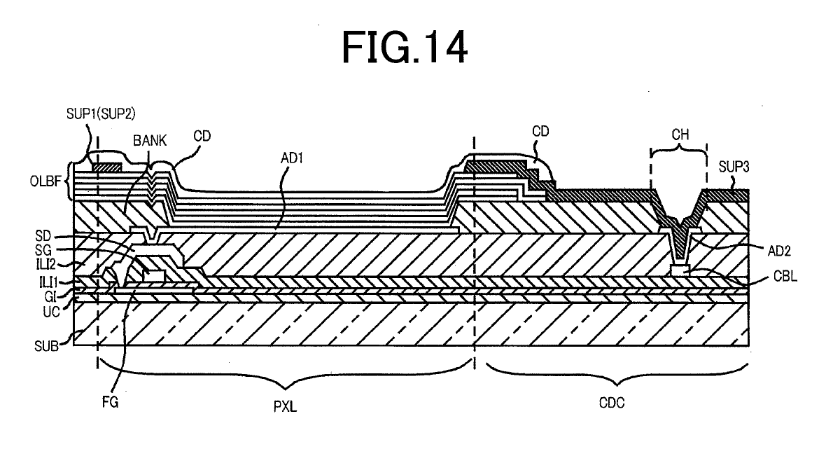

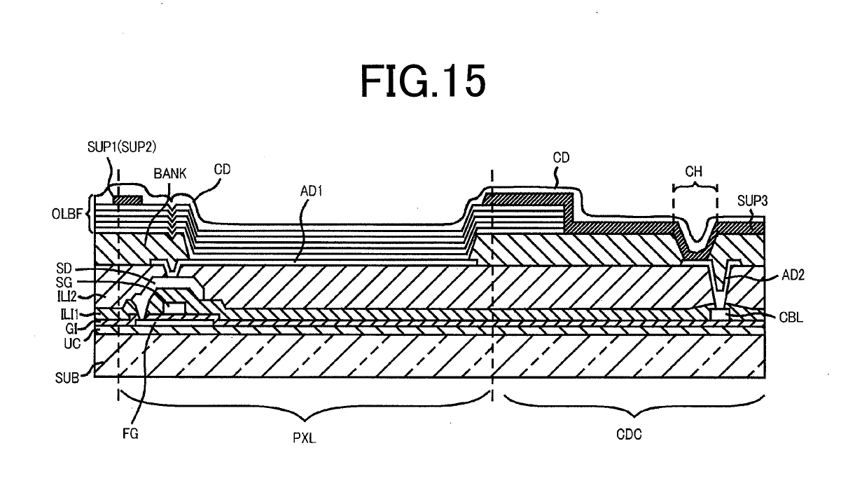

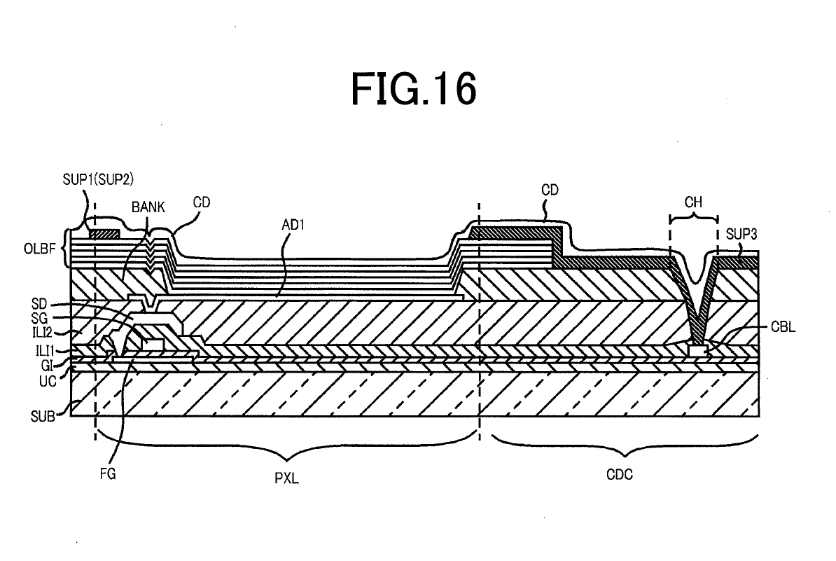

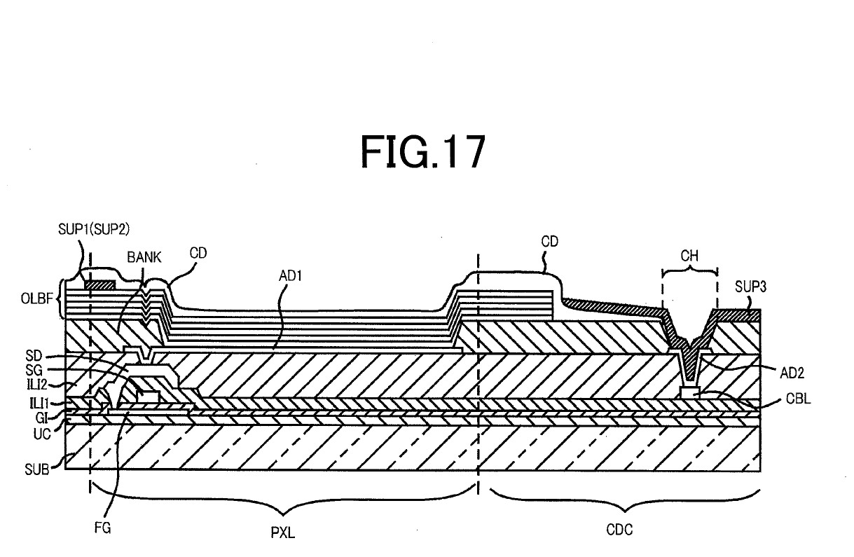

FIG. 13 differs from FIG. 12 in that the upper electrode CD is formed immediately before the first contact hole CH1. FIG. 14 differs from FIG. 9 in that at least one functional layer OLBF is protruded and the upper electrode CD covers up to the protruded position. FIG. 15 differs from FIG. 12 in that the cathode bus line CBL is formed not in the second electrode layer SD but in the first electrode layer SG. FIG. 16 differs from FIG. 9 in that the cathode bus line CBL is formed not in the second electrode layer SD but in the first electrode layer SG. FIG. 17 differs from FIG. 9 in that the upper electrode CD is formed up to immediately before the cathode contact CH and the auxiliary electrode is formed thereon.

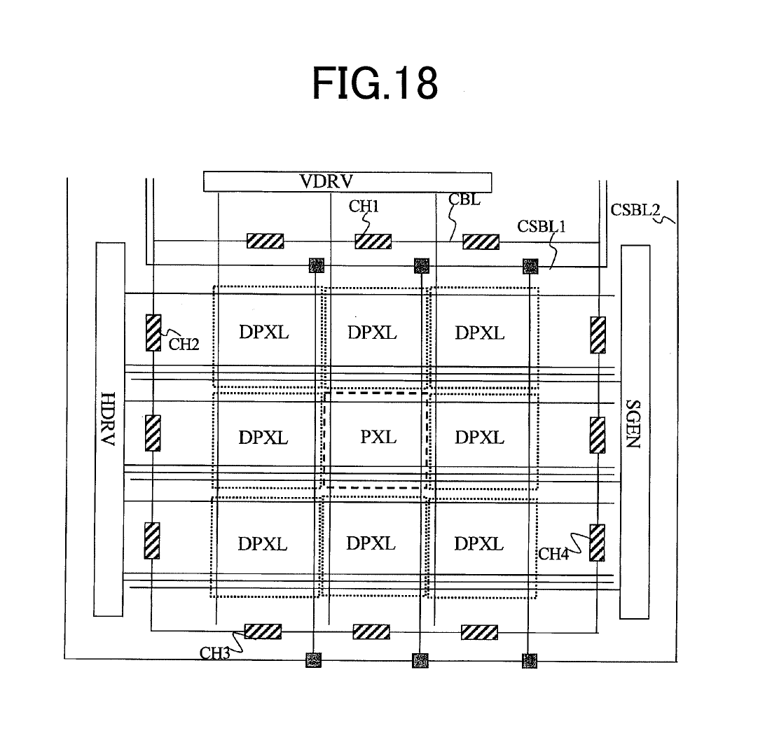

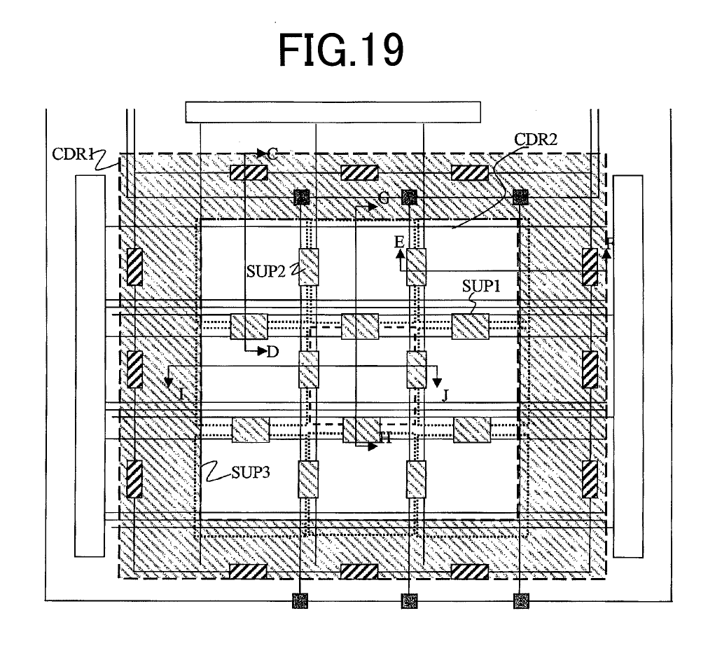

The block diagram of the first substrate SUB1 having a dummy pixel DPXL is present is shown in FIG. 18 and FIG. 19. FIG. 18 differs from FIG. 7 in that the pixels on the outermost circumference are dummy pixels DPXL. FIG. 19 differs from FIG. 8 also in that the pixels on the outermost circumference are dummy pixels DPXL. In both Figures, there is no opening in any dummy pixel DPXL.

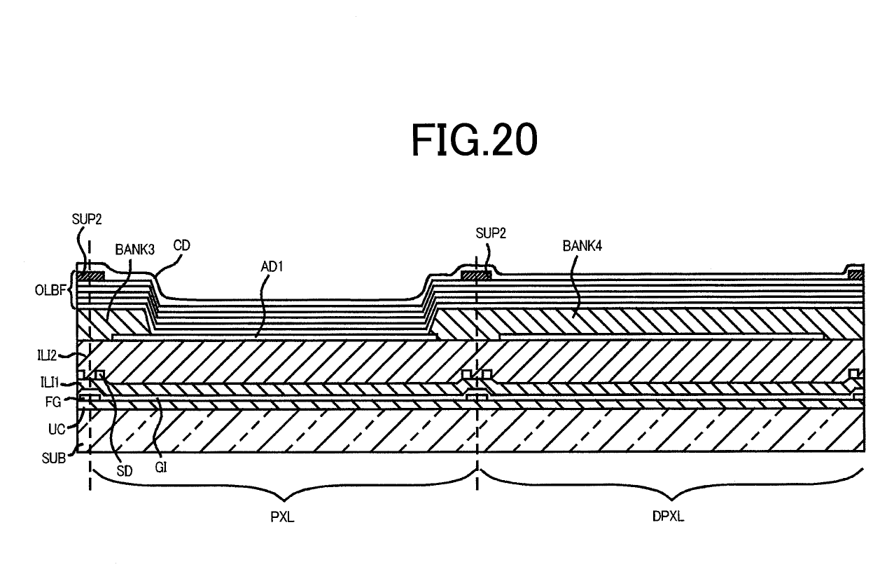

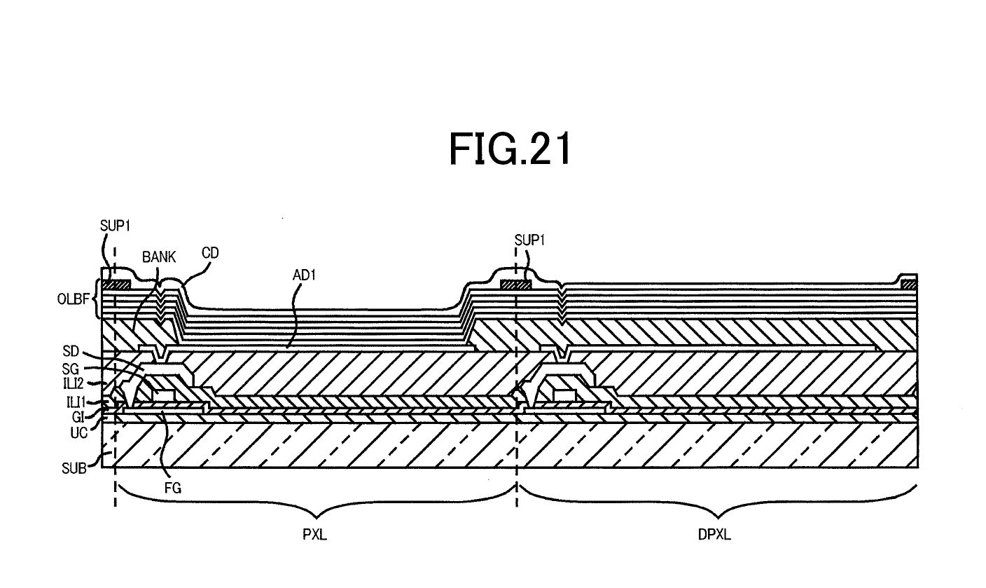

An example cross-sectional structure of the first substrate SUB1 taken along the G-H line of FIG. 19 is shown in FIG. 20. FIG. 20 is a cross-sectional view of horizontally neighboring two pixels: a dummy pixel DPXL and a display pixel PXL. An example cross-sectional structure of the first substrate SUB1 taken along the I-J line of FIG. 19 is shown in FIG. 21.

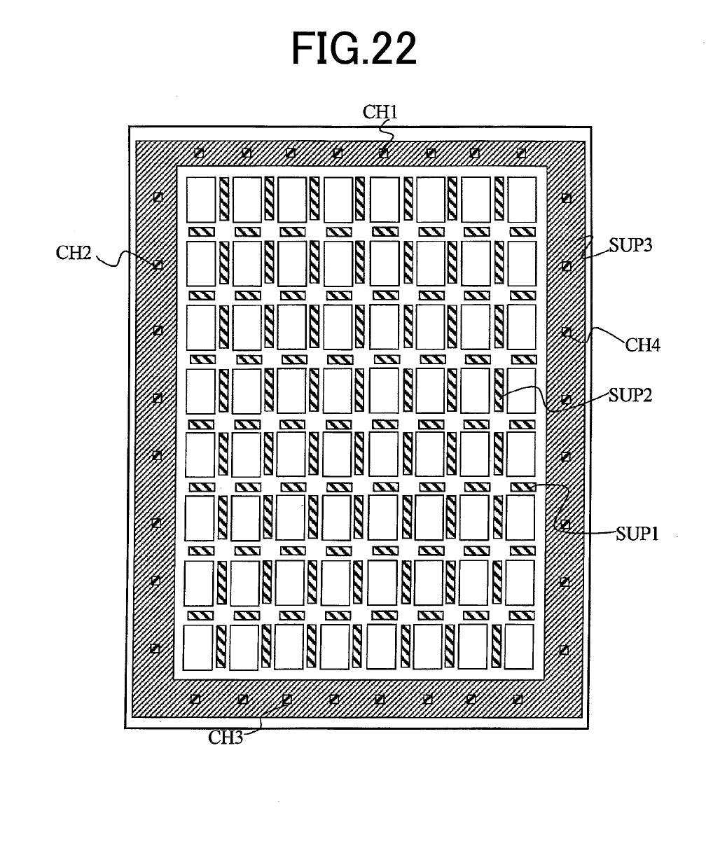

FIG. 22 to FIG. 31 are plan views showing the planar layout of the auxiliary electrode. The structure of FIG. 22 is such that the third auxiliary electrode SUP3 is formed around the effective display area (AR) in a frame shape and connected to the cathode bus line CBL (for example, refer to FIG. 18) at the contact holes (cathode contacts) CH(CH1, CH2, CH3, and CH4) arranged along the four (vertical and horizontal) sides. The cathode contacts CH are formed on a row and column basis of the rectangular pixels PXL (refer to FIG. 7) arranged in the effective display area (AR). Furthermore, the first auxiliary electrode SUP1 and the second auxiliary electrode SUP2 are formed between pixels PXL. The first auxiliary electrodes SUP1, which are horizontally-long rectangular electrodes, are auxiliary electrodes formed on banks between vertically neighboring pixels PXL (top-to-bottom direction of Figure). Each of these electrodes is independent on a pixel PXL basis at the top and bottom positions and the left and right (horizontal) positions of each pixel PXL. The second auxiliary electrodes SUP2, which are vertically-long rectangular electrodes, are auxiliary electrodes formed on banks between horizontally neighboring pixels PXL. Each of these electrodes is independent on a pixel PXL basis at all four positions of each pixel PXL. However, it is not necessary that the above-mentioned auxiliary electrodes be formed between all pixels PXL, nor that the formation unit be between luminescence areas as long as they are formed on banks. Specifically, an area without a first auxiliary electrode SUP1 between luminescence areas, and an area with a first auxiliary electrode SUP1 between luminescence areas may be arranged in a parallel manner.

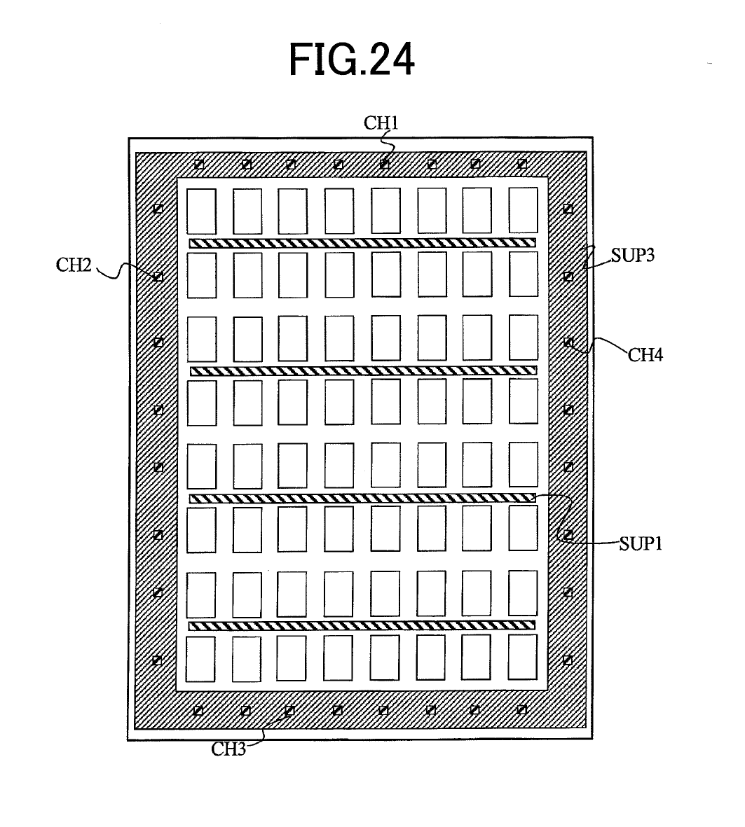

FIG. 23 differs from FIG. 22 in that none of the second auxiliary electrodes SUP2 shown in FIG. 22 are formed. FIG. 24 differs from FIG. 23 in that all the first auxiliary electrodes SUP1 are connected. Any desired first auxiliary electrodes SUP1 may be connected. It is not necessary that all the first auxiliary electrodes SUP1 are connected. Specifically, assuming that there are X pixels PXL in the vertical direction and there are y first auxiliary electrodes SUP1 in the vertical direction, a relationship of x>y is acceptable.

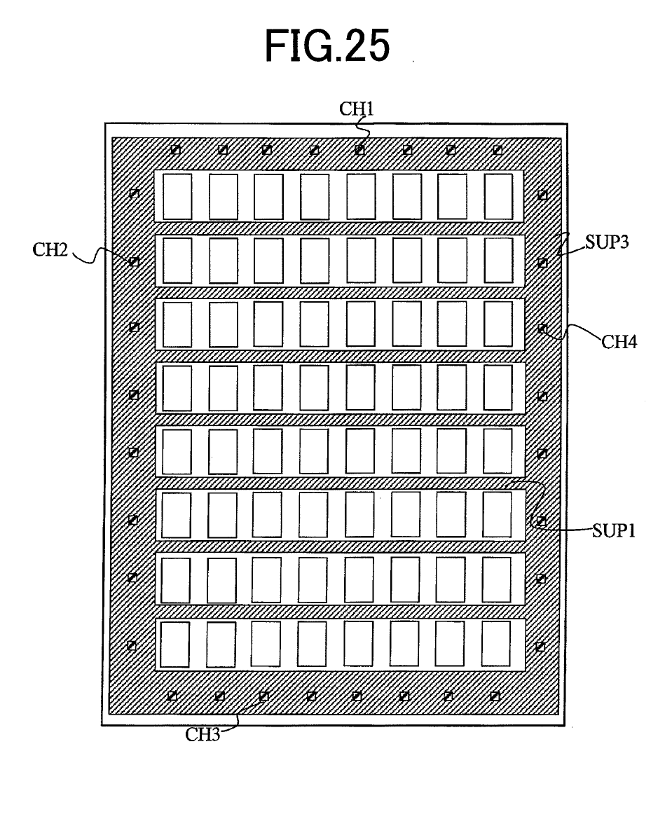

FIG. 25 differs from FIG. 24 in that all the first auxiliary electrodes SUP1 are connected with the third auxiliary electrodes SUP3. In FIG. 25, all the first auxiliary electrodes SUP1 are connected with the third auxiliary electrodes SUP3; however, it is necessary that at least one first auxiliary electrode SUP1 be connected with third auxiliary electrode SUP3.

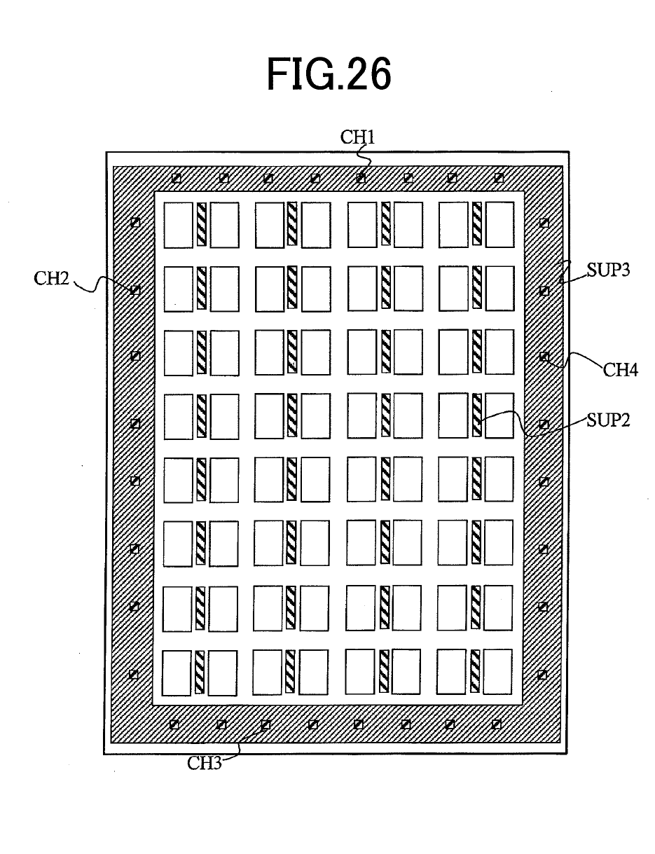

FIG. 26 differs from FIG. 22 in that none of the first auxiliary electrodes SUP1 shown in FIG. 22 are formed.

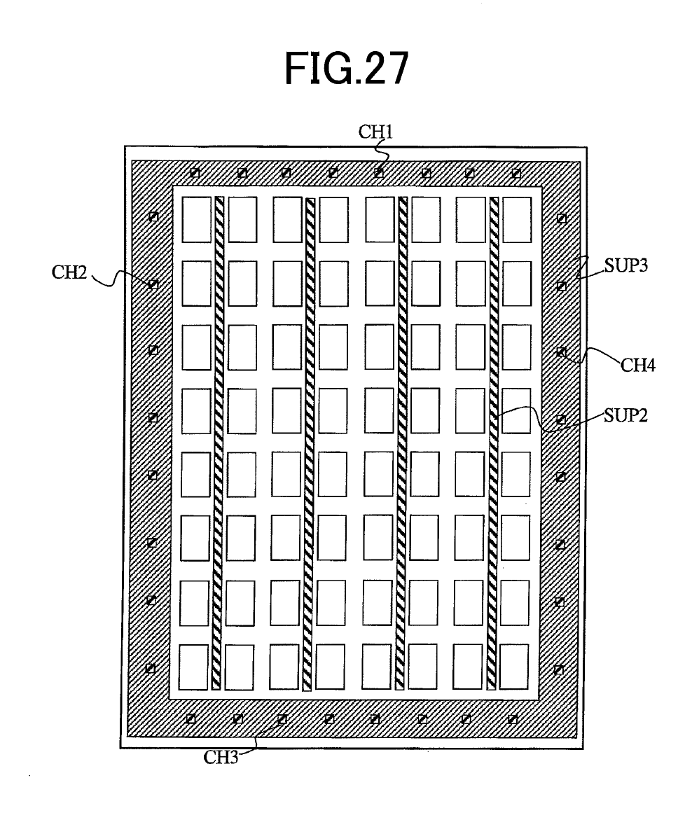

FIG. 27 differs from FIG. 26 in that all the second auxiliary electrodes SUP2 are connected. It would be possible that any desired second auxiliary electrodes SUP2, not necessarily all ones, are connected. Specifically, assuming that there are v pixels PXL in the horizontal direction and there are w second auxiliary electrodes SUP2 in the horizontal direction, a relationship of v>w is acceptable.

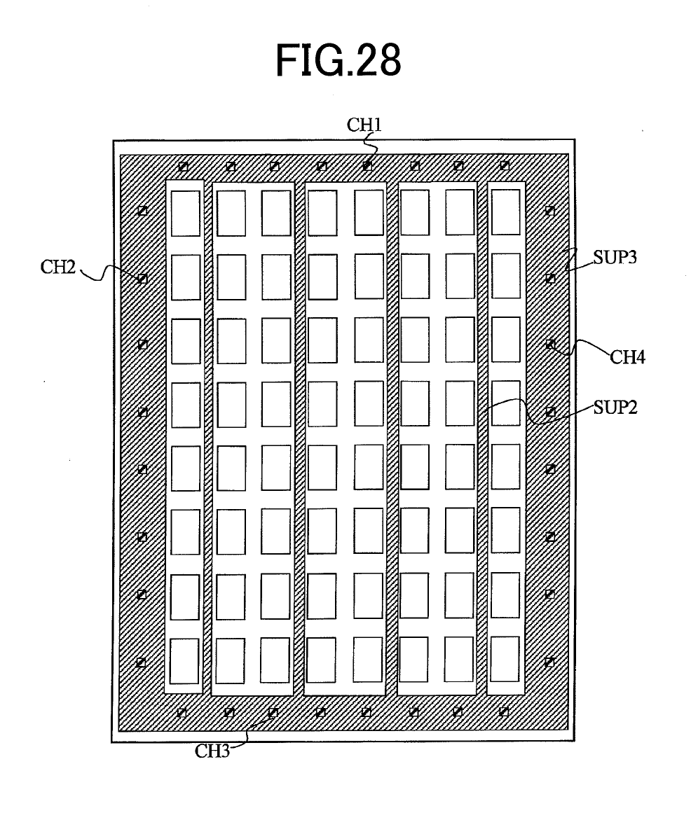

FIG. 28 differs from FIG. 27 in that all the second auxiliary electrode SUP2 are connected with the third auxiliary electrodes SUP3. In this FIG. 28, all the second auxiliary electrodes SUP2 are connected with the third auxiliary electrodes SUP3; however, it would be possible that at least one second auxiliary electrode SUP2, not necessarily all ones, is connected with the third auxiliary electrode SUP3.

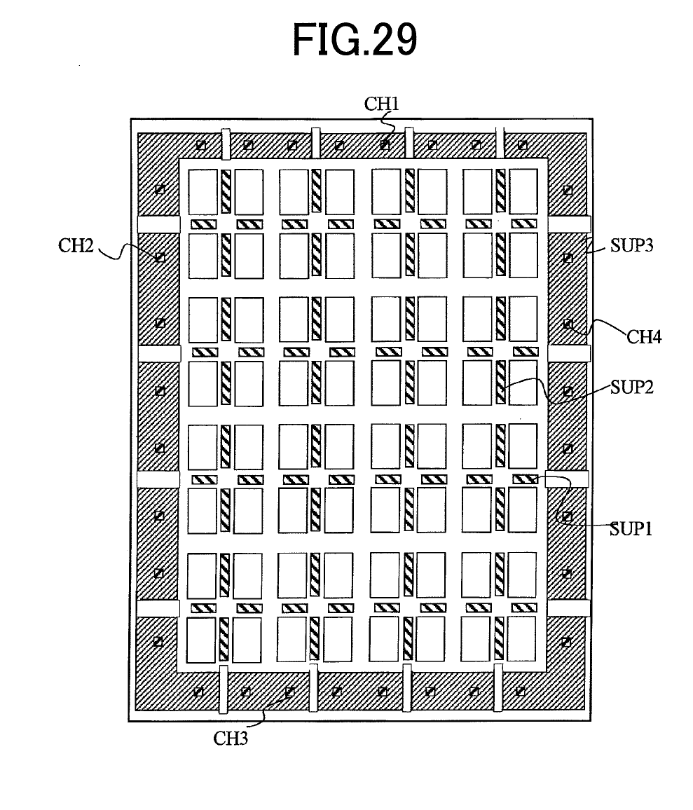

FIG. 29 differs from FIG. 22 in that the third auxiliary electrode SUP3 is segmentalized. In the case of FIG. 29, the third auxiliary electrode is segmentalized on all four sides; however, it may be segmentalized only on any one side. Furthermore, there is one segmentalized section for each two pixels PXL, but not limited thereto; however, it would be possible that there is only one segmentalized section for each pixel PXL or for a plurality of pixels PXL. Furthermore, it would be possible that there are segmentalized sections not at horizontal and vertical positions between luminescence areas but at horizontal and vertical positions of luminescence areas.

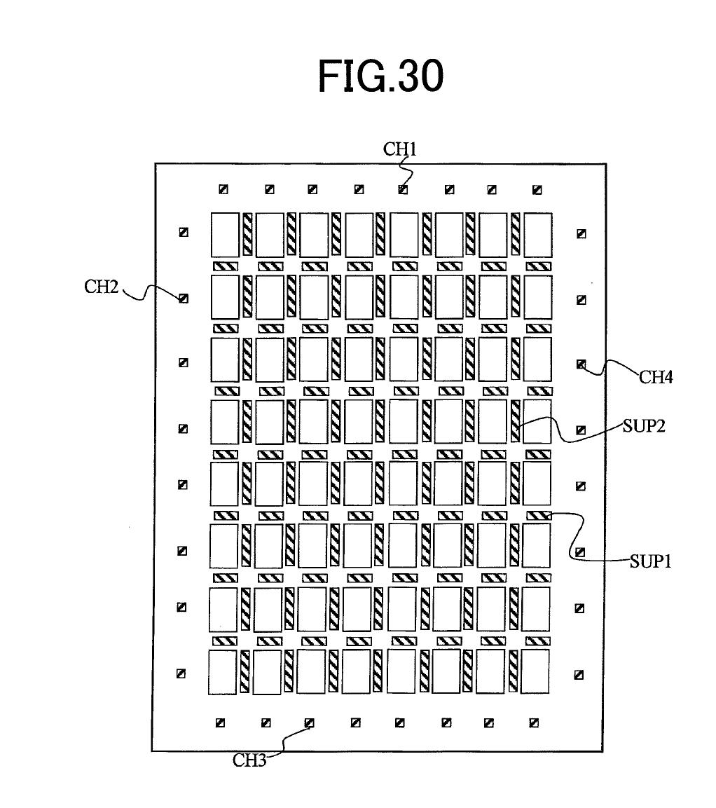

FIG. 30 differs from FIG. 22 in that the third auxiliary electrode SUP3 is not formed.

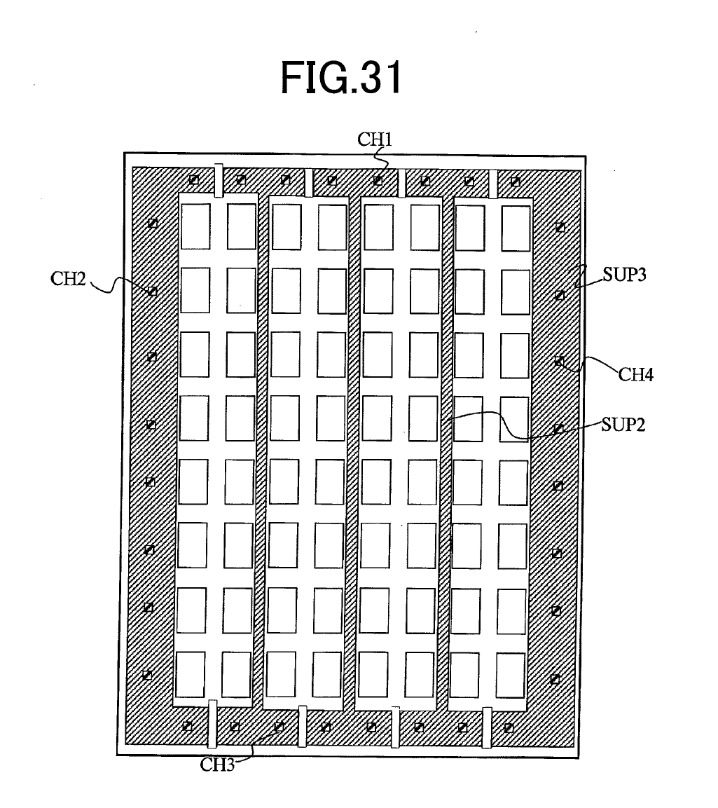

FIG. 31 differs from FIG. 28 in that segmentalized sections in the third auxiliary electrode SUP3 are prepared only in the direction in which the second auxiliary electrodes SUP2 extend, i.e., in the vertical direction of the effective display area AR.

What is claimed is:

1. An organic electroluminescence display device comprising:
a plurality of active elements; and
a plurality of organic electroluminescence elements which produce multi-color luminescence through control by the active elements, the plurality of active elements and the plurality of organic electroluminescence elements being formed on a substrate;
wherein
the organic electroluminescence elements each have a lower electrode, a functional layer containing an organic layer, and an upper electrode laminated in this order from the substrate side;
the upper electrode of the plurality of organic electroluminescence elements is a common electrode to all the organic electroluminescence elements; and
an auxiliary electrode made of a material equivalent to that of the upper electrode or a material with a conductivity higher than that of the upper electrode is formed between the upper electrode and the functional layer.

2. An organic electroluminescence display device comprising:
a plurality of active elements; and
a plurality of organic electroluminescence elements which produce luminescence through control by the active elements, the plurality of active elements and the plurality of organic electroluminescence elements being formed on a substrate;
wherein
the organic electroluminescence element has a lower electrode, a functional layer containing an organic layer, and an upper electrode laminated in this order from the substrate side;
the upper electrode of the plurality of organic electroluminescence elements is a common electrode to the plurality of organic electroluminescence elements;
a metal electrode is provided between the upper electrode and the organic layer; and
the sheet resistance between two points on the upper electrode which sandwich the metal electrode is lower than that between two points which do not sandwich the metal electrode.

3. The organic electroluminescence display device according to claim 1, wherein
an insulating film is provided between the lower electrode and the organic layer; and
the auxiliary electrode is provided at a position of overlapping with the insulating film.

4. The organic electroluminescence display device according to claim 1, wherein
the auxiliary electrode is arranged between the plurality of organic electroluminescence elements.

5. The organic electroluminescence display device according to claim 1, wherein
the auxiliary electrode is arranged between the adjacent lower electrodes.

6. The organic electroluminescence display device according to claim 1, wherein
the plurality of organic electroluminescence elements are arranged in a matrix form; and
the auxiliary electrode extends in a row direction or in a column direction on a screen.

7. The organic electroluminescence display device according to claim 1, wherein
the auxiliary electrode is formed outside an effective display area.

8. The organic electroluminescence display device according to claim 7, wherein
at least a part of the auxiliary electrode is connected with a wiring below the organic layer outside the effective display area.

9. The organic electroluminescence display device according to claim 8, wherein
at the connecting section, the upper electrode is provided above said auxiliary electrode.

10. The organic electroluminescence display device according to claim 8, wherein
an electrode in the same layer as said lower electrode exists between said wiring below organic layer and said auxiliary electrode.

11. The organic electroluminescence display device according to claim 8, wherein
said wiring below the organic layer is a wiring in the same layer as that of a source electrode or a drain electrode of the active element.

12. The organic electroluminescence display device according to claim 1, wherein
the upper electrode is a transparent conductive film.

13. The organic electroluminescence display device according to claim 12, wherein
the transparent conductive film contains a light-permeable thin metal film containing ITO, IZO or ZnO.

14. The organic electroluminescence display device according to claim 1, wherein
the lower electrode contains a non-light-impermeable thin metal film.

15. The organic electroluminescence display device according to claim 14, wherein
the lower electrode includes a structure in which a transparent conductive film is laminated on the non-light-impermeable thin metal film.

16. An organic electroluminescence display device comprising:
an organic electroluminescence element;
a vertical drive circuit;
a scanning line;
a first active element which captures a data signal for each pixel by means of the vertical drive circuit and the scanning line; and
a second active element which controls the amount of current passed in the organic electroluminescence element by means of a data signal captured for each pixel by the first active element, the organic electroluminescence element, the vertical drive circuit, the scanning line, the first active element, and the second active element being formed on a substrate;
wherein
the organic electroluminescence element includes a lower electrode, an organic layer, and a light-permeable upper electrode laminated in this order from the substrate side;
a first insulating film is formed between the active element and the lower electrode;
a second insulating film having an opening formed on the lower electrode is formed between the fringe of the lower electrode and the first insulating film and above the vertical drive circuit and the scanning line;
the organic layer is formed on the opening and the second insulating film;
the upper electrode is arranged above the opening and formed commonly with a plurality of pixels; and
a metal layer is formed between the upper electrode and the organic layer, at a position of overlapping with the second insulating film, between the upper electrode and the second insulating film.

17. The organic electroluminescence display device according to claim 16, wherein
the sheet resistance of the upper electrode when the metal layer is formed becomes lower than that when the metal layer is not formed.

18. The organic electroluminescence display device according to claim 2, wherein
an insulating film is provided between the lower electrode and the organic layer; and
the metal electrode is provided at a position of overlapping with the insulating film.

19. The organic electroluminescence display device according to claim 2, wherein
the metal electrode is arranged between the plurality of organic electroluminescence elements.

20. The organic electroluminescence display device according to claim 2, wherein
the metal electrode is arranged between the adjacent lower electrodes.
